(19) United States
(12) Patent Application Publication
(10) Pub. No.: US 2025/0151372 A1
(43) Pub. Date: May 8, 2025

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Chun Yi CHOU, Hsinchu City (TW); Guan-Lin CHEN, Hsinchu County (TW); Shi Ning JU, Hsinchu City (TW); Kuo-Cheng CHIANG, Hsinchu County (TW); Chih-Hao WANG, Hsinchu County (TW)

(73) Assignee: TAIWAN SEMICONDUCTOR MANUFACTURING COMPANY, LTD., Hsinchu (TW)

(21) Appl. No.: 18/501,172

(22) Filed: Nov. 3, 2023

(51) Int. Cl. H01L 21/8234; H01L 27/088

(52) U.S. Cl. CPC H10D 84/038; H10D 84/0128; H10D 84/83

(57) ABSTRACT

A method includes forming first semiconductive sheets over a substrate and arranged in a vertical direction, and second semiconductive sheets over the substrate and arranged in the vertical direction, wherein a number of the second semiconductive sheets is different than a number of the first semiconductive sheets; forming first source/drain regions on either side of each of the first semiconductive sheets, and second source/drain regions on either side of each of the second semiconductive sheets; forming a first gate around each of the first semiconductive sheets, and a second gate around each of the second semiconductive sheets.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-22 illustrate schematic views of intermediate stages of semiconductor structures in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the course of IC evolution, functional density (i.e., the number of interconnected devices per chip area) has generally increased while geometry size (i.e., the smallest component (or line) that can be created using a fabrication process) has decreased. As part of this evolution, the development and application of nanosheet (NS) stack structures have discussed. However, the nanosheet structures may present a limitation: the nanosheet stack structure remains consistent across different areas of a single wafer. This uniformity poses challenges. Given that various regions of a semiconductor device may necessitate distinct transistor characteristics, a one-size-fits-all approach to nanosheet structures proves inadequate. Therefore, the present disclosure in various embodiments provides a method to incorporate multiple nanosheet stack structures on one wafer. By allowing different nanosheet stack structures on distinct areas of a single wafer, this disclosure facilitates a more tailored and efficient design, catering to the specific needs of different semiconductor regions. Different regions can now have transistors with characteristics best suited for their specific functions, potentially boosting overall device performance.

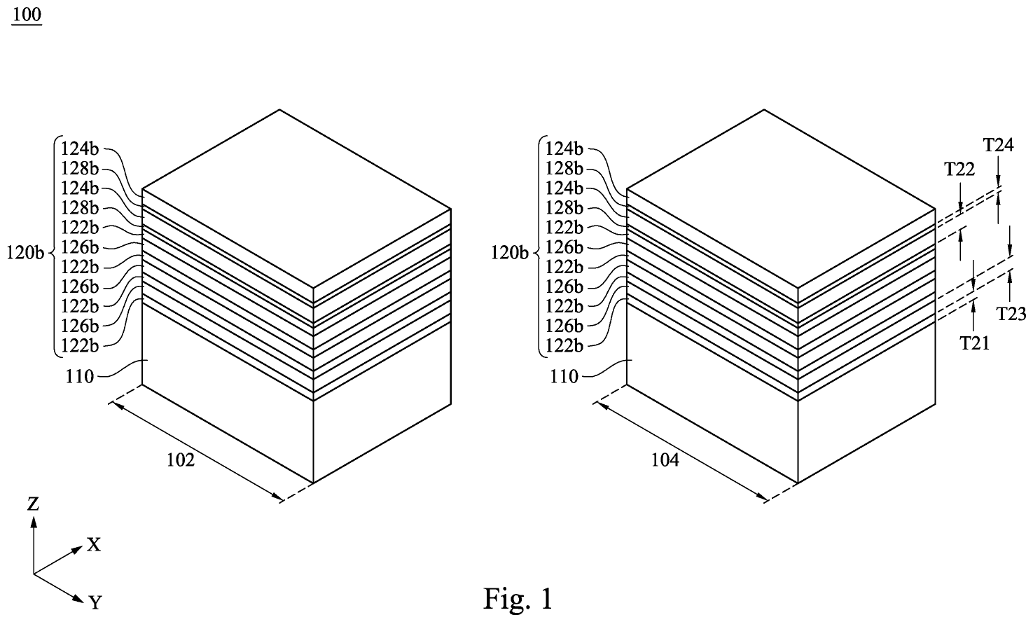

Reference is made to FIGS. 1-22. FIGS. 1-22 illustrate schematic views of intermediate stages in the formation of a semiconductor structure 100 in accordance with some embodiments. In addition to the semiconductor structure 100, FIGS. 1-22 depict X-axis, Y-axis, and Z-axis directions. It is understood that additional operations can be provided before, during, and after the processes shown by FIGS. 1-22, and some of the operations described below can be replaced or eliminated, for additional embodiments of the method. The order of the operations/processes may be interchangeable.

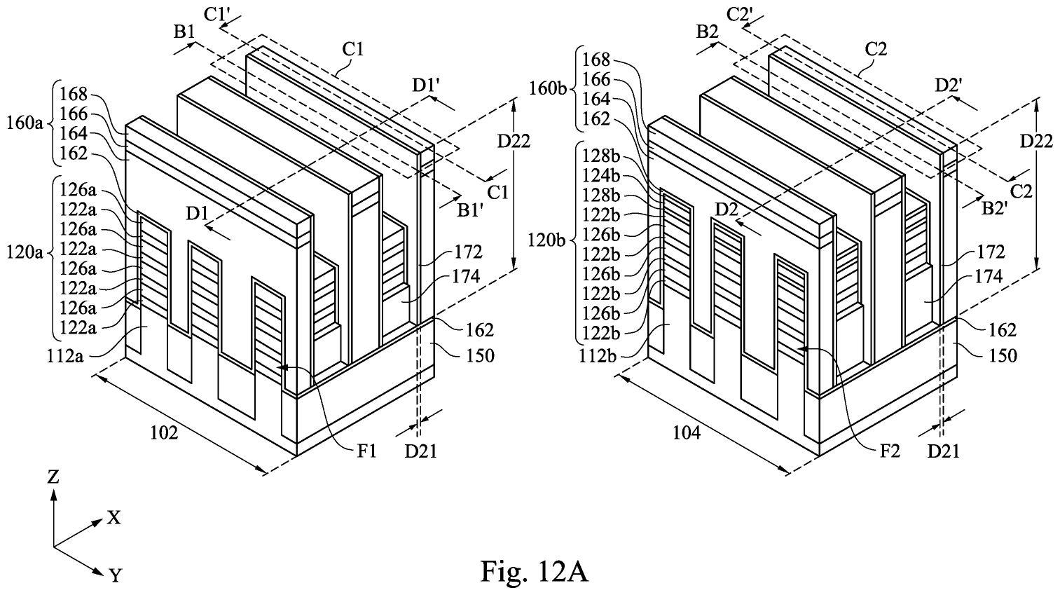

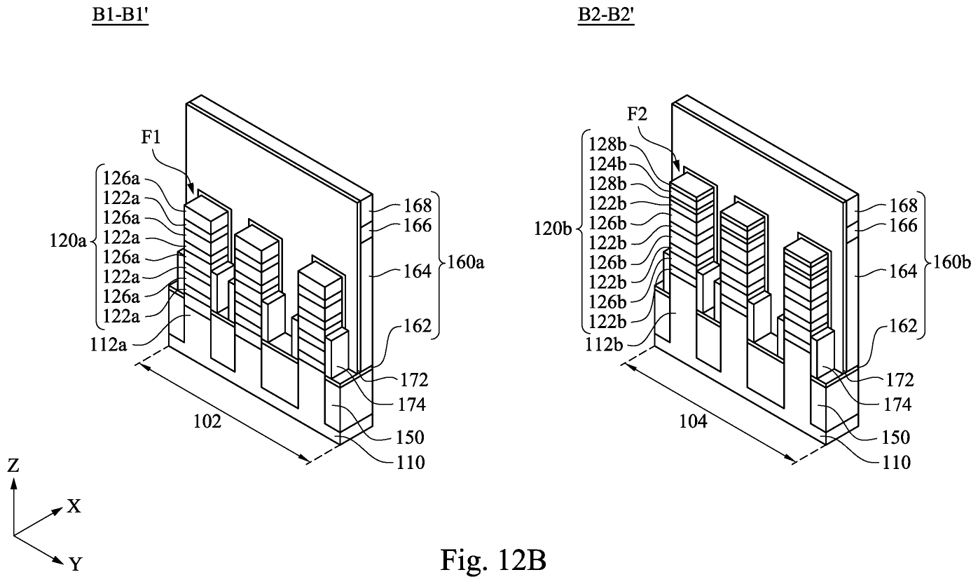

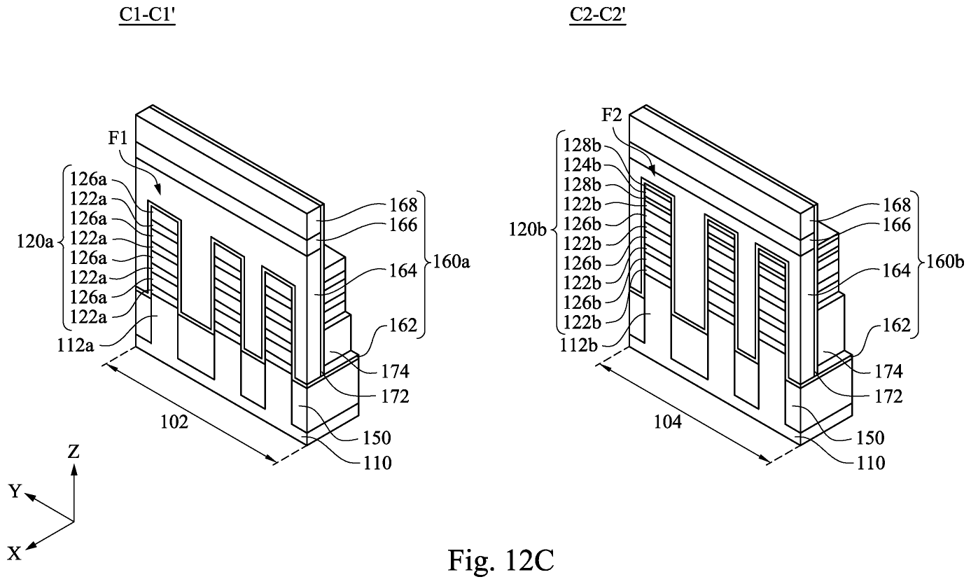

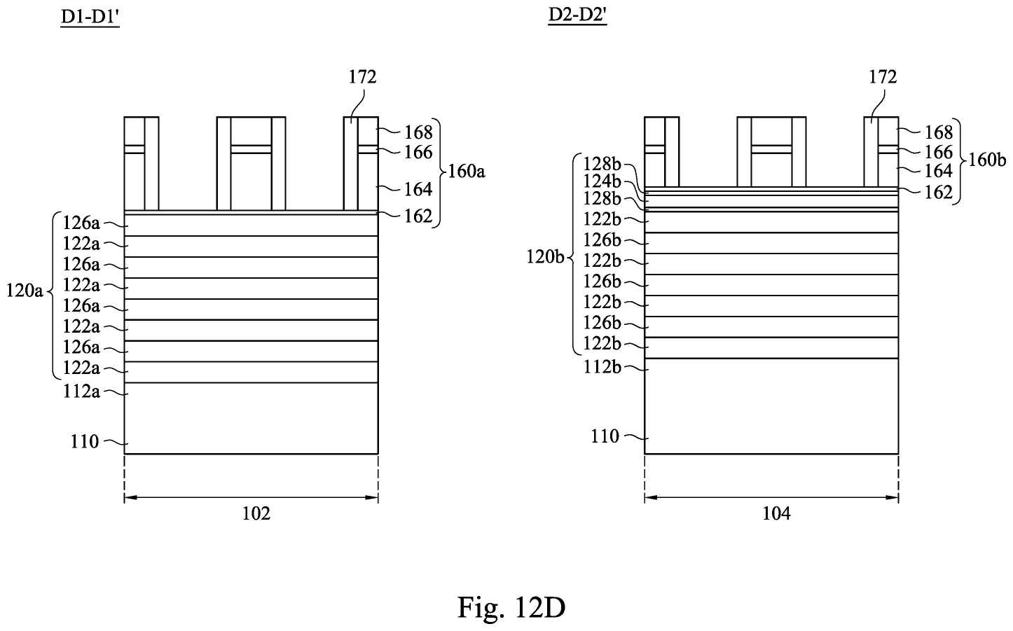

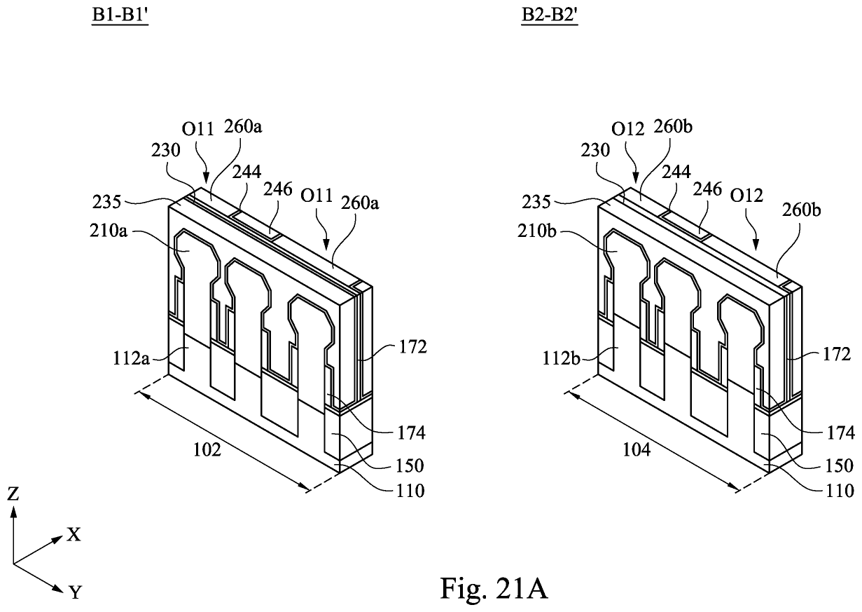

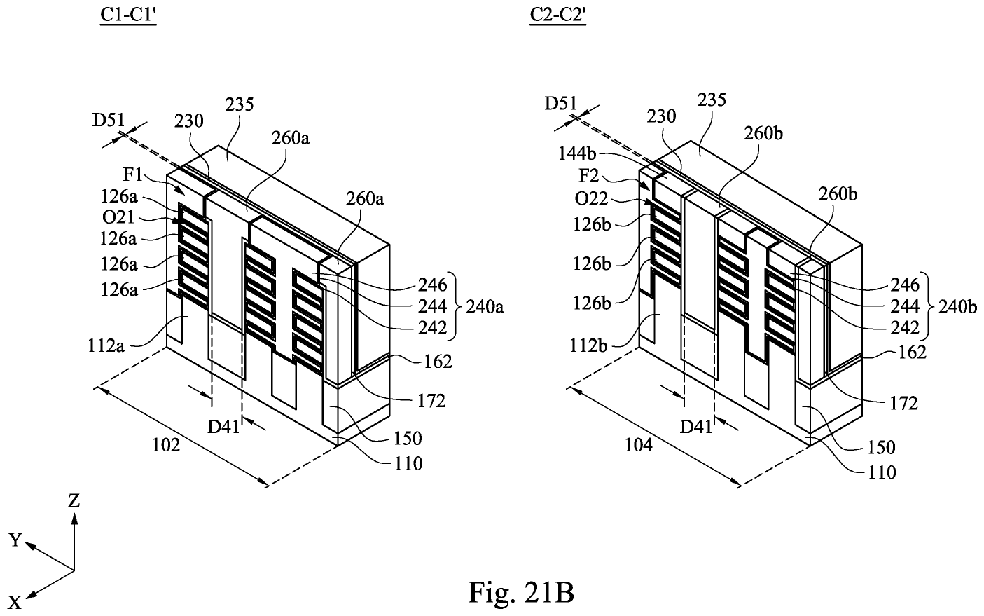

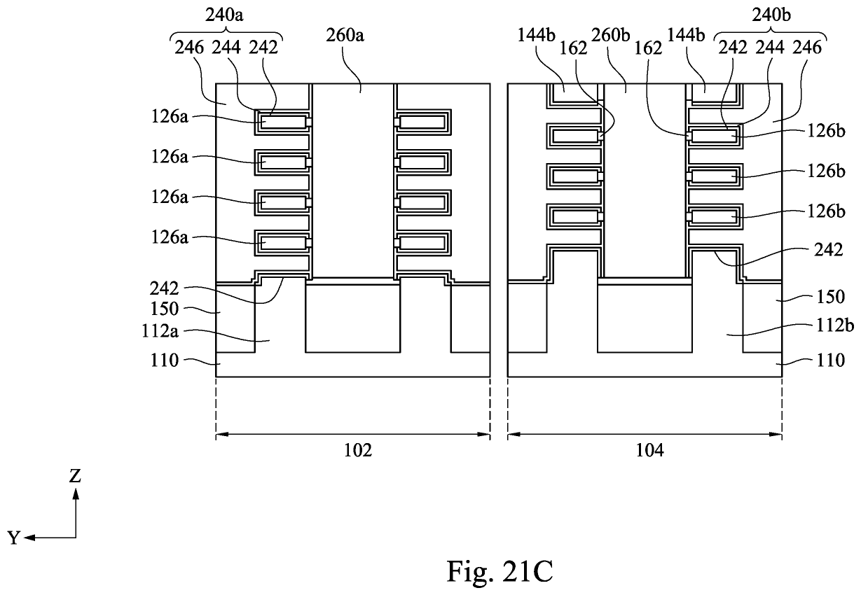

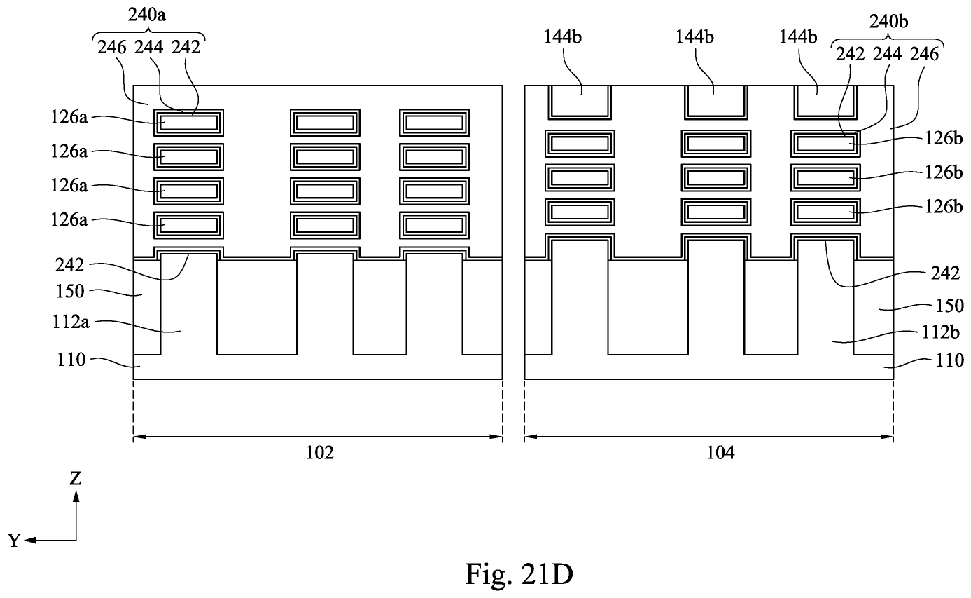

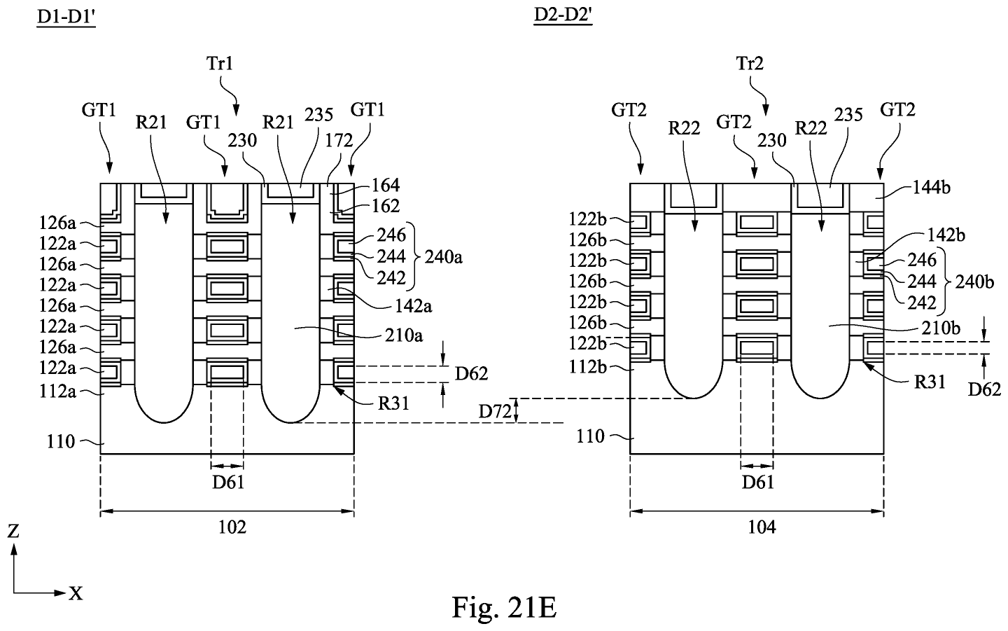

FIGS. 1-12A are perspective views in the formation of the semiconductor structure 100 in accordance with some embodiments. FIGS. 12B, 13A, 14A, 15A, 16A, 17A, 18A, 19A, 20A, and 21A are cross-sectional perspective views taken along lines B1-B1′ and B2-B2′ as shown in FIG. 12A. FIGS. 12C, 13B, 14B, 15B, 16B, 17B, 18B, 19B, 20B, and 21B are cross-sectional perspective views taken along lines C1-C1′ and C2-C2′ in regions C1 and C2 as shown in FIG. 12A. FIGS. 12D, 13C, 14C, 15C, 16C, 17C, 18C, 19C, 20C, 21E, and 22 are cross-sectional views taken along lines D1-D1′ and D2-D2′ as shown in FIG. 12A. FIG. 21C is a cross-sectional view corresponding to FIG. 21B. FIG. 21D is a cross-sectional view of a semiconductor structure 100a corresponding to FIG. 21C according to some embodiments of the present disclosure.

Reference is made to FIG. 1. A substrate 110 is provided. In some embodiments, the substrate 110 is made of a suitable elemental semiconductor, such as silicon, diamond or germanium; a suitable alloy or compound semiconductor, such as Group-IV compound semiconductors (silicon germanium (SiGe), silicon carbide (SiC), silicon germanium carbide (SiGeC), GeSn, SiSn, SiGeSn), Group III-V compound semiconductors (e.g., gallium arsenide, indium gallium arsenide InGaAs, indium arsenide, indium phosphide, indium antimonide, gallium arsenic phosphide, or gallium indium phosphide), or the like. Further, the substrate 110 may include an epitaxial layer (epi-layer), which may be strained for performance enhancement, and/or may include a silicon-on-insulator (SOI) structure. In some embodiments, the substrate 110 can be interchangeably referred to as a semiconductor substrate.

The substrate 110 has a first device region 102 and a second device region 104. The first device region 102 is a region in which first transistors (or first nanostructure devices) will reside, and the second device region 104 is a region in which second transistors (or second nanostructure devices) will reside. In some embodiments, the first transistors are different from the second transistors at least in the device size. For example, first transistors in the first device region 102 may be denser than the second transistors in the second device region 104. By way of example and not limitation, the first transistors in the first device region 102 may be applied to some regions of a circuit (e.g., logic) with low current, while the second transistors in the second device region 104 may be applied to some other regions of the circuit with high current (and high computing speed).

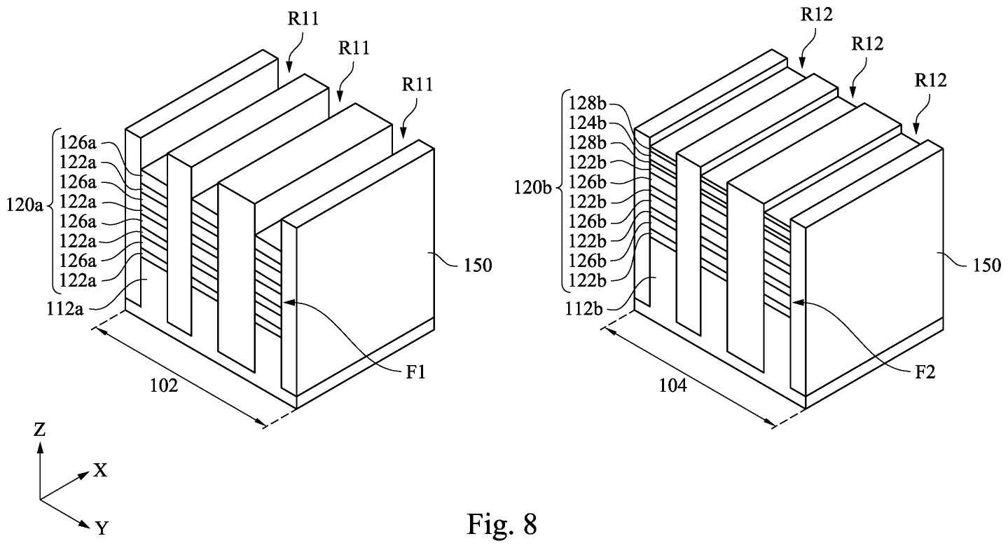

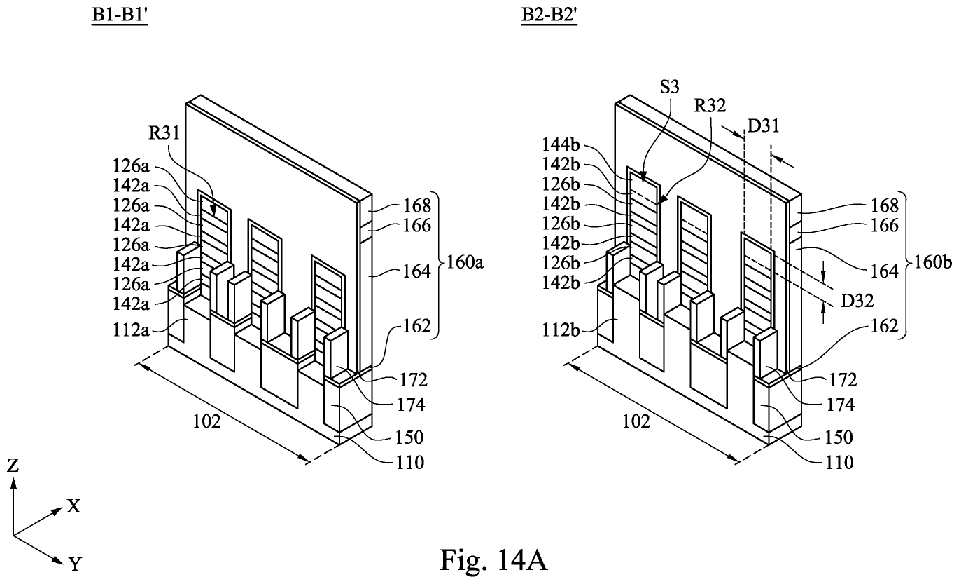

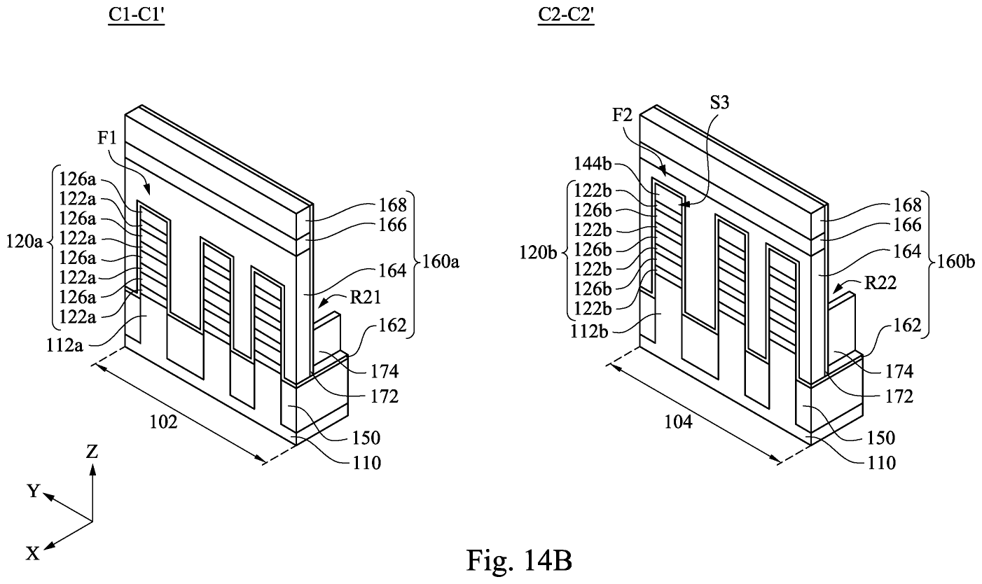

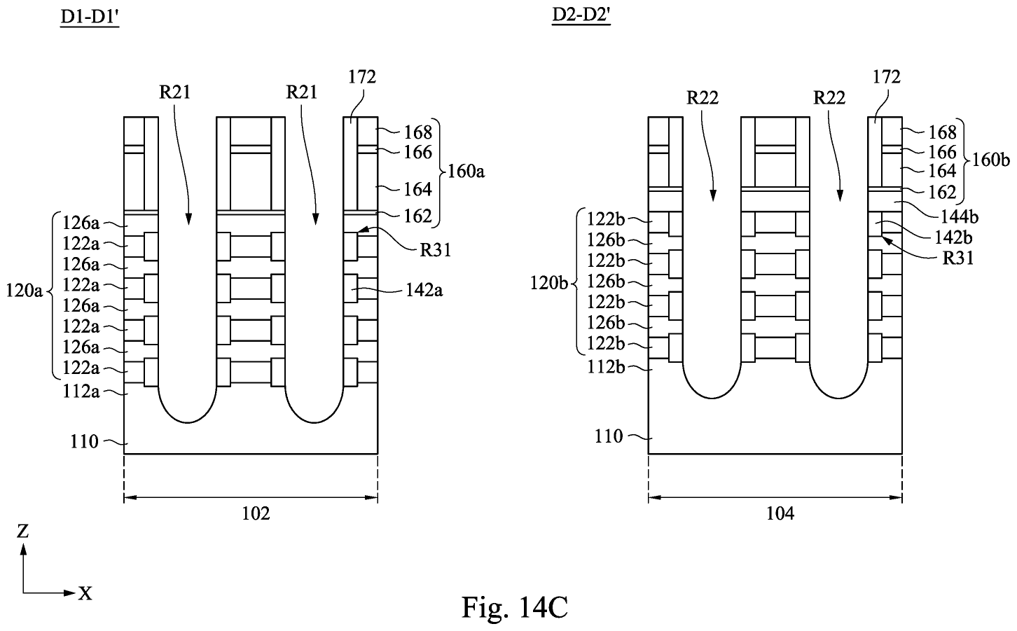

A semiconductor stack 120b is formed on the substrate 110 through epitaxy, such that the semiconductor stack 120b forms crystalline layers. The semiconductor stack 120b includes semiconductor layers 122b, 124b, 126b, and 128b stacked alternatively. There may be two, three, four, or more of the semiconductor layers 122a, 124b, 126b, and 128b. The semiconductor layers 122b and 124b may be silicon germanium (SiGe) layers. The semiconductor layers 124b have a higher germanium atomic concentration than the semiconductor layers 122b. Specifically, the higher germanium atomic concentration in the semiconductor stack 120b, the greater etching rate of the etching process (see FIGS. 8 and 14C) is. By way of example and not limitation, the germanium atomic concentration of semiconductor layers 122b can be in a range from about 10 to 30%, such as about 10, 15, 20, 25, or 30%. In some embodiments, the germanium atomic concentration of semiconductor layers 124b can be in a range from about 30 to 45%, such as about 30, 35, 40, or 45%. As shown in FIG. 1, the semiconductor layer 124b can have a thickness T22 substantially the same as a thickness T21 of the semiconductor layer 122b. In some embodiments, the thickness T22 of the semiconductor layer 124a can be less than or greater than the thickness T21 of the semiconductor layer 122b.

The semiconductor layers 126b and 128b may be pure silicon layers that are free from germanium. The semiconductor layers 126b and 128b may also be substantially pure silicon layers, for example, with a germanium percentage lower than about 1 percent. Furthermore, the semiconductor layers 126b and 128b may be intrinsic, which are not doped with p-type and n-type impurities. In some other embodiments, however, the semiconductor layers 126b and 128b can be silicon germanium or germanium for p-type semiconductor device, or can be III-V materials, such as InAs, InGaAs, InGaAsSb, GaAs, InPSb, or other suitable materials. As shown in FIG. 1, the semiconductor layer 128b can have a thickness T24 thinner than a thickness T23 of the semiconductor layer 126b. In addition, the thickness T24 of the semiconductor layer 128b can also be thinner than the semiconductor layer 122b and/or the semiconductor layer 124b.

The semiconductor layers 126b or portions thereof may form nanostructure channel(s) of nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are fork-sheets, nanosheets, nanowires, nanoslabs, or nanorings, depending on their geometry. The use of the semiconductor layers 126b to define a channel or channels of the semiconductor device is further discussed below. In some embodiments, the semiconductor layer 126b can be interchangeably referred to as a channel region, a channel pattern, a channel structure, a nanostructure, a nanostructural pedestal, or a semiconductor sheet.

As described above, the semiconductor layers 126b may serve as channel region(s) for a subsequently-formed semiconductor device and the thickness is chosen based on device performance considerations. The semiconductor layers 122b, 124b, and 128b in channel regions(s) may eventually be removed and serve to define a vertical distance between adjacent channel region(s) for a subsequently-formed multi-gate device and the thickness is chosen based on device performance considerations.

Accordingly, the semiconductor layers 122b, 124b, and 128b may also be referred to as sacrificial layers, and the semiconductor layers 126b may also be referred to as channel layers.

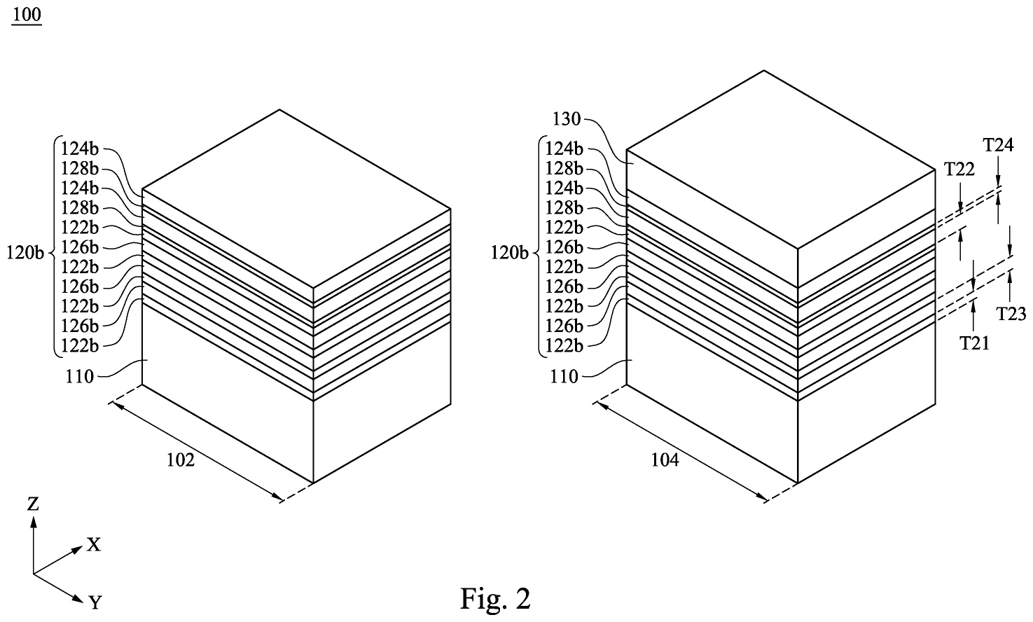

Reference is made to FIG. 2. A patterned hard mask 130 is formed over the semiconductor stack 120b. The patterned hard mask 130 covers the second device region 104 while leave the first device region 102 uncovered. In some examples, the patterned hard mask 130 is deposited on the semiconductor stack 120b by thermally grown process, chemical vapor deposition (CVD) process, and/or atomic layer deposition (ALD) process. In some embodiments, the patterned hard mask 130 may includes SiO₂, SiN, SiCN, SiCON, SiCO, AlO, HfO, other suitable materials, combinations thereof, multiple layers thereof, or the like.

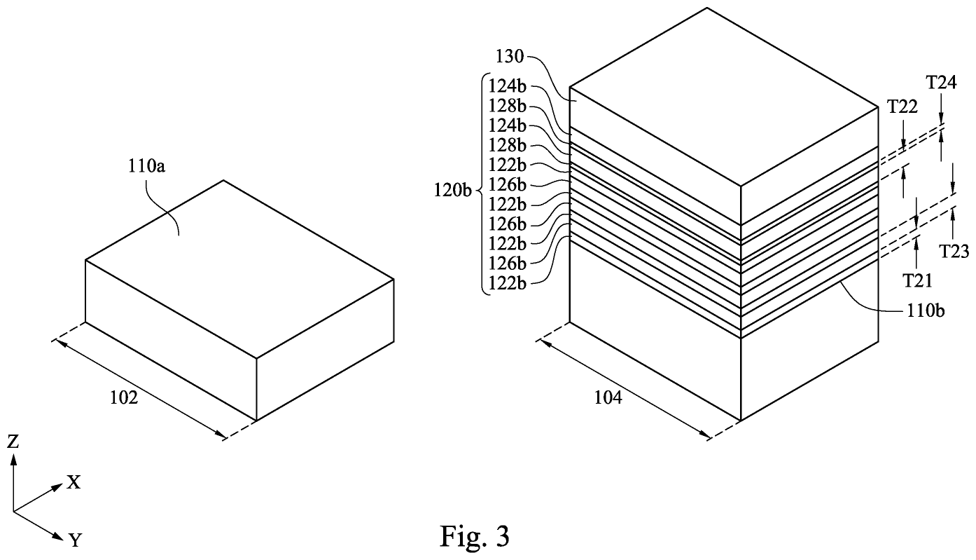

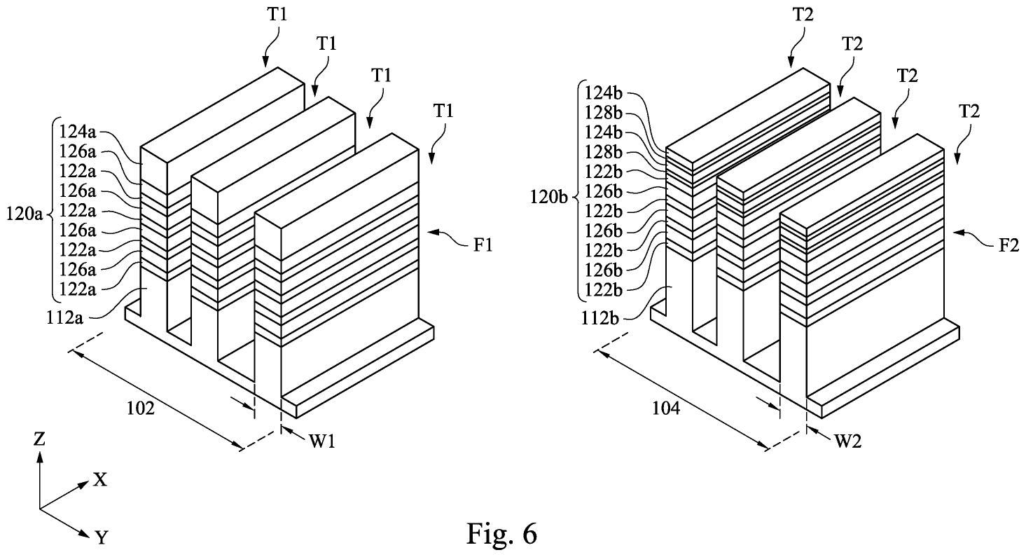

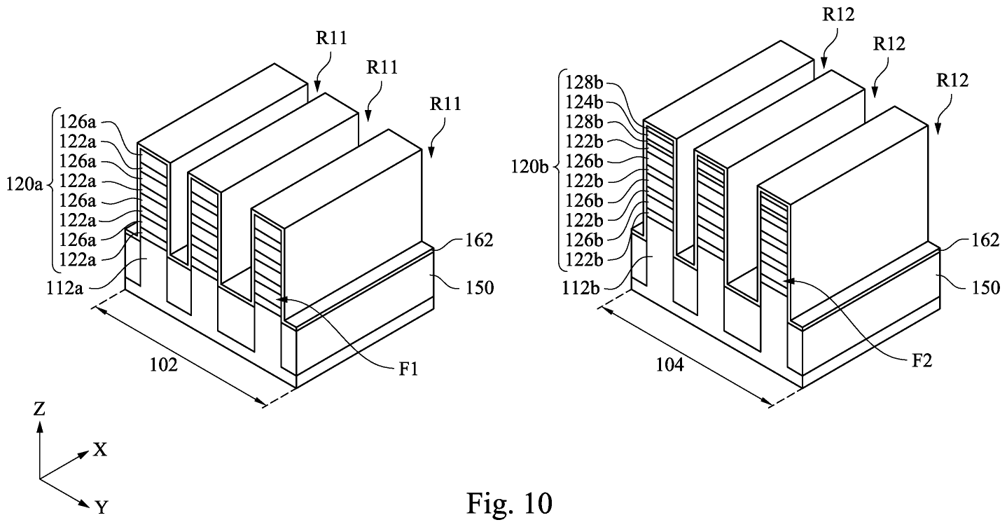

Reference is made to FIG. 3. The semiconductor stack 120b and the substrate 110 of FIG. 2 are patterned using the patterned hard mask 130 as etching masks. Accordingly, the semiconductor stack 120b on the first device region 102 can be moved. In some embodiments, the etching process would consume a portion of the substrate 110 on the first device region 102, and thus a top surface 110t of the substrate 110 on the first device region 102 may be lowered as shown in FIG. 10. Specifically, a top surface 110a of the substrate 110 on the first device region 102 can be lower than a top surface 110b of the substrate 110 on the second device region 104, such that protrusion structure 112b (see FIG. 6) has a top surface in a higher level height than the protrusion structure 112a (see FIG. 6).

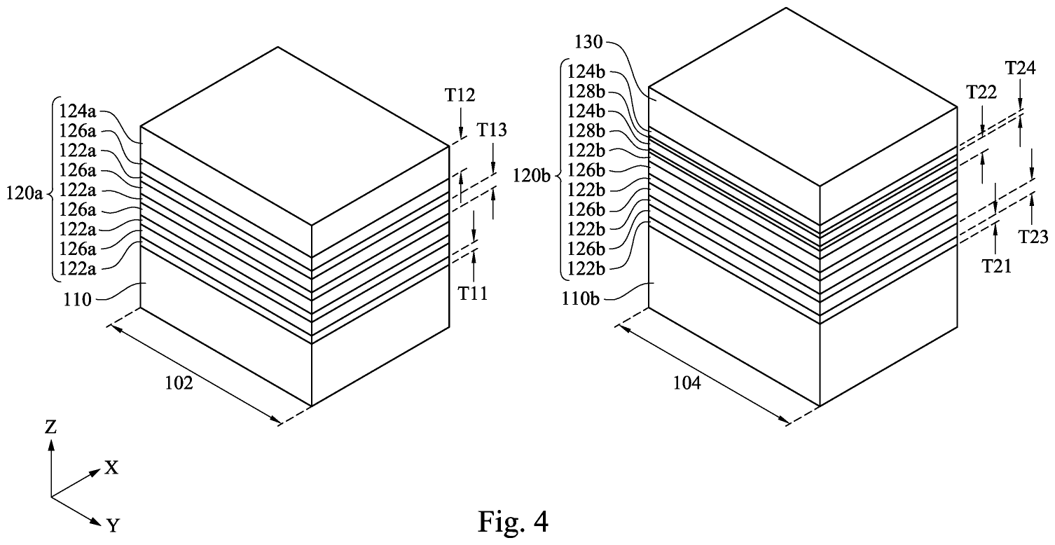

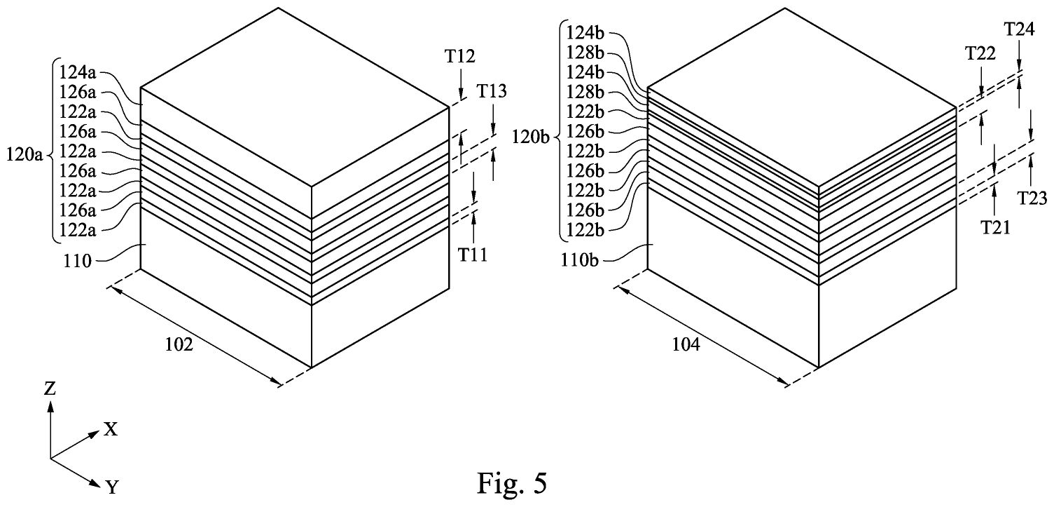

Reference is made to FIGS. 4 and 5. A semiconductor stack 120a is formed on the first device region 102 of the substrate 110 through epitaxy, such that the semiconductor stack 120a forms crystalline layers. The semiconductor stack 120a includes semiconductor layers 122a, 124a, and 126a stacked alternatively. There may be two, three, four, or more of the semiconductor layers 122a, 124a, and 126a. The semiconductor layers 122a and 124a may be silicon germanium (SiGe) layers. The semiconductor layers 124a have a higher germanium atomic concentration than the semiconductor layers 122a. Specifically, the higher germanium atomic concentration in the semiconductor stack 120a, the greater etching rate of the etching process is (see FIG. 8). By way of example and not limitation, the germanium atomic concentration of semiconductor layers 122a can be in a range from about 10 to 30%, such as about 10, 15, 20, 25, or 30%. In some embodiments, the germanium atomic concentration of semiconductor layers 124a can be in a range from about 30 to 45%, such as about 30, 35, 40, or 45%. As shown in FIG. 4, the semiconductor layer 124a can have a thickness T12 greater than a thickness T11 of the semiconductor layer 122a. The thickness T12 may be greater than the thicknesses T21, T22, T23, and T24 of the semiconductor layers 122b, 124b, 126b, and 128b. In some embodiments, the thickness T22 of the semiconductor layer 124b can be less than or substantially the same as the thickness T11 of the semiconductor layer 122a.

The semiconductor layers 126a may be pure silicon layers that are free from germanium. The semiconductor layers 126a may also be substantially pure silicon layers, for example, with a germanium percentage lower than about 1 percent. Furthermore, the semiconductor layers 126a may be intrinsic, which are not doped with p-type and n-type impurities. In some other embodiments, however, the semiconductor layers 126a can be silicon germanium or germanium for p-type semiconductor device, or can be III-V materials, such as InAs, InGaAs, InGaAsSb, GaAs, InPSb, or other suitable materials. As shown in FIG. 4, the semiconductor layer 126a can have a thickness T13 can be greater than the thickness T11 of the semiconductor layer 122a, and less than the thickness T12 of the semiconductor layer 124a.

The semiconductor layers 126a or portions thereof may form nanostructure channel(s) of nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are fork-sheets, nanosheets, nanowires, nanoslabs, or nanorings, depending on their geometry. The use of the semiconductor layers 126a to define a channel or channels of the semiconductor device is further discussed below. In some embodiments, the semiconductor layer 126a can be interchangeably referred to as a channel region, a channel pattern, a channel structure, a nanostructure, or a semiconductor sheet.

As described above, the semiconductor layers 126a may serve as channel region(s) for a subsequently-formed semiconductor device and the thickness is chosen based on device performance considerations. The semiconductor layers 122a and 124a in channel regions(s) may eventually be removed and serve to define a vertical distance between adjacent channel region(s) for a subsequently-formed multi-gate device and the thickness is chosen based on device performance considerations. Accordingly, the semiconductor layers 122a and 124a may also be referred to as sacrificial layers, and the semiconductor layers 126a may also be referred to as channel layers. In some embodiments, the topmost semiconductor layers 124a and 124b can be interchangeably referred to as mask layers. Subsequently, the patterned hard mask 130 is then removed by using, for example, etching or ashing process as shown in FIG. 5.

Reference is made to FIG. 6. The semiconductor stacks 120a and 120b and the substrate 110 shown in FIG. 5 are patterned using a patterned hard mask (not shown) as etching masks to form trenches T1 and T2. Accordingly, a plurality of fin structures (or semiconductor strips or active regions) F1 and F2 are formed over the first and second device regions 102 and 104. The trenches T1 and T2 extend into the substrate 110 and have lengthwise directions substantially parallel to each other. The trenches T1 and T2 form protrusion structures 112a and 112b in the substrate 110, where the protrusion structures 112a and 112b protrude from the substrate 110, and the fin structures F1 and F2 are respectively formed above the protrusion structures 112a and 112b of the substrate 110. The remaining portions of the semiconductor stack 120a and 120b are accordingly referred to as the fin structures F1 and F2 alternatively. The fin structure F1 can have a width W1, and the fin structure F2 can have a width W2. In some embodiments, the width W2 of the fin structure F2 can be substantially the same as the width W1 of the fin structure F1. In some embodiments, the width W2 of the fin structure F2 can be different form the width W1 of the fin structure F1. By way of example and not limitation, the width W2 of the fin structure F2 can be greater than or less the width W1 of the fin structure F1. In some embodiments, a vertical dimension (or height) of the protrusion structure 112b within the second device region 104 can be greater than a vertical dimension (or height) of the protrusion structure 112a within the first device region 102. In some embodiments, the protrusion structures 112a and 112b can be interchangeably referred to as fin strips, fin patterns, or nanostructured pedestal.

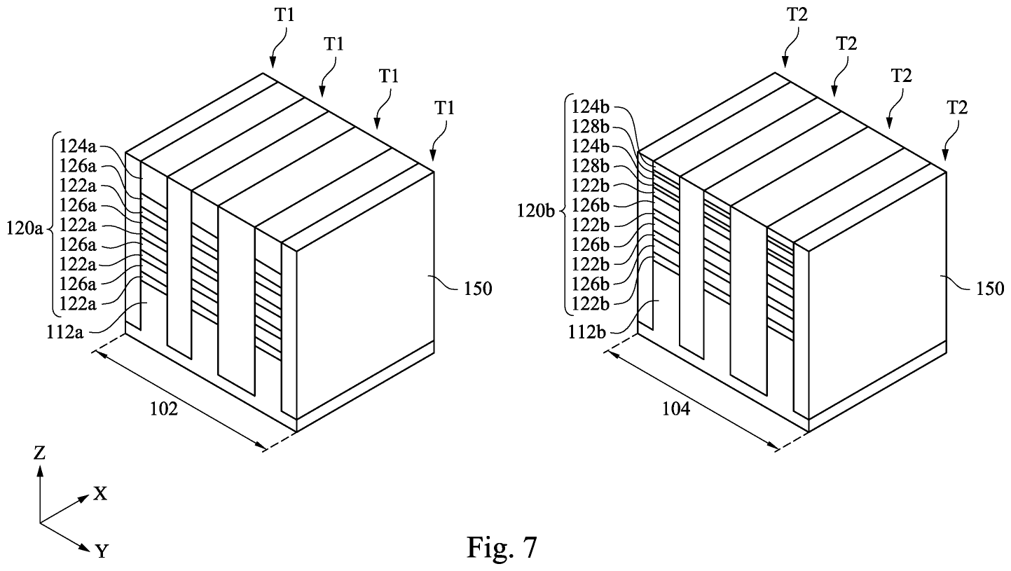

Reference is made to FIG. 7. Isolation structures 150, such as shallow trench isolations (STI), are disposed in the trenches T1 and T2 and over the substrate 110. The isolation structures 150 can be equivalently referred to as an isolation insulating layer in some embodiments. The isolation structures 150 may be made of suitable dielectric materials such as silicon oxide, silicon nitride, silicon oxynitride, fluorine-doped silicate glass (FSG), low-k dielectrics such as carbon doped oxides, extremely low-k dielectrics such as porous carbon doped silicon dioxide, a polymer such as polyimide, combinations of these, or the like. In some embodiments, the isolation structures 150 are formed through a process such as CVD, flowable CVD (FCVD), or a spin-on-glass process, although any acceptable process may be utilized. Subsequently, portions of the isolation structures 150 extending over the top surfaces of the fin structures F1 and F2 are removed using, for example, an etching back process, chemical mechanical polishing (CMP), or the like.

Reference is made to FIG. 8. The topmost semiconductor layer 124a and 124b are removed by using suitable etch techniques, resulting in recesses R11 and R12 recessing from top surfaces of the isolation structures 150. This operation may be performed by using a selective etching process. By way of example and not limitation, the semiconductor layers 124a and 124b are SiGe and the semiconductor layers 126a and 128b are silicon allowing for the selective etching of the topmost semiconductor layers 124a and 124b. In some embodiments, the selective dry etching etches SiGe at a faster etch rate than it etches Si. As a result, the topmost semiconductor layers 124a and 124b can be removed from the semiconductor layers 126a and 128b. On the other hand, an upper one of the semiconductor layers 124b in the second device region 104 is removed while leave the lower one of the semiconductor layers 124b in the second device region 104 remained.

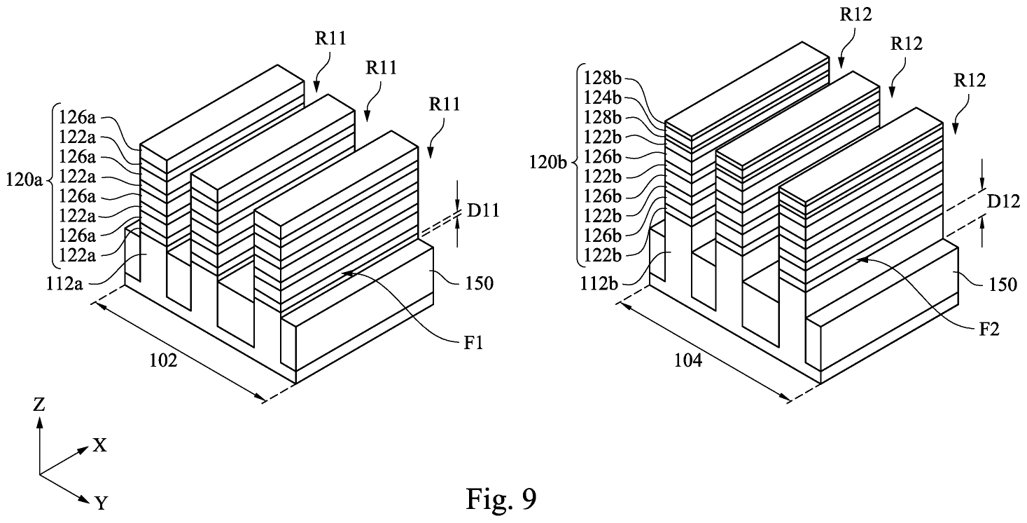

Reference is made to FIG. 9. Subsequently, the isolation structures 150 are recessed and around at least portions of the protrusion structures 112a and 112b, such that at least portions of the semiconductor stacks 120a and 120b protrude from between adjacent isolation structures 150. In some embodiments, the top surfaces of the isolation structures 150 are coplanar (within process variations) with the top surfaces of the protrusion structures 112a and 112b. In some embodiments, the top surfaces of the isolation structures 150 are above or below the top surfaces of the protrusion structures 112a and 112b. As shown in FIG. 9, a top surface of protrusion structures 112a (or mesa) and a top surface of the recessed isolation structures 150 within the first device region 102 has a distance D11 (or STI step height) therebetween, and a top surface of protrusion structures 112b (or mesa) and a top surface of the recessed isolation structures 150 within the second device region 104 has a distance D12 (or STI step height) therebetween. In some embodiments, the distance D12 can be greater than distance D11 in a range from about 1 to 40 nm, such as 1, 5, 10, 15, 20, 25, 30, 35, or 40 nm.

The isolation structures 150 separate the features of adjacent devices. In some embodiments, the isolation structures 150 are recessed using a single etch processes, or multiple etch processes. In some embodiments in which the isolation structures 150 is made of silicon oxide, the etch process may be, for example, a dry etch, a chemical etch, or a wet cleaning process. For example, the chemical etch may employ fluorine-containing chemical such as dilute hydrofluoric (dHF) acid. In some embodiments, the space defined by isolation structure 150 can be called an isolation space.

Reference is made to FIG. 10. A dielectric layer 162 is formed over the first and second device regions 102 and 104 of the substrate 110. Specifically, the dielectric layer 162 can be blanket formed over the substrate 110 to cover the semiconductor stack 120a and 120b, the protrusion structures 112a and 112b, and the isolation structures 150. In some embodiments, the dielectric layer 162 may be made of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multi-layer structure including a plurality of dielectric layers. In some embodiments, the dielectric layer 162 may be made of high-k dielectric materials, such as metal oxides, transition metal-oxides, or the like. Examples of the high-k dielectric material include, but are not limited to, hafnium oxide (HfO₂), hafnium silicon oxide (HfSiO), hafnium tantalum oxide (HfTaO), hafnium titanium oxide (HfTiO), hafnium zirconium oxide (HfZrO), zirconium oxide, titanium oxide, aluminum oxide, hafnium dioxide-alumina (HfO₂—Al₂O₃) alloy, or other applicable dielectric materials. In some embodiments, the dielectric layer 162 can be an oxide layer. The gate dielectric layer 162 may be formed by a deposition processes, such as chemical vapor deposition (CVD), physical vapor deposition (PVD), atomic layer deposition (ALD), plasma enhanced CVD (PECVD) or other suitable techniques. In some embodiments, the dielectric layer 162 can be interchangeably referred to as an oxide layer, a gate dielectric layer, or a dummy dielectric layer.

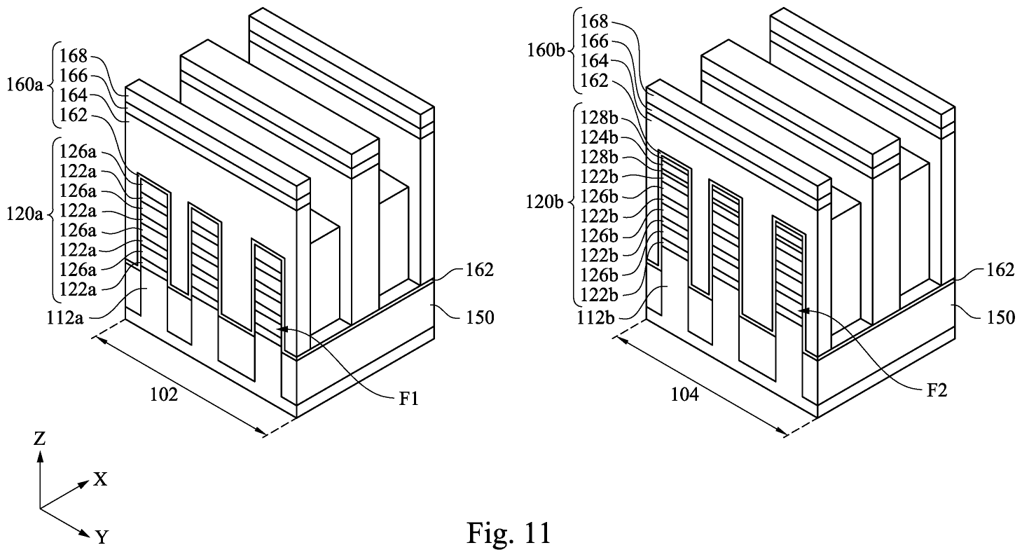

Reference is made to FIG. 11. Dummy gate structures 160a and 160b are formed to extend across the semiconductor stack 120a and 120b and the protrusion structures 112a and 112b. The dummy gate structures 160a and 160b each may include a gate dielectric layer 162, a dummy gate electrode layer 164 over the gate dielectric layer 162, and dielectric layers 166 and 168 over the dummy gate electrode layer 164. The dummy gate electrode layer 164 is formed over the dielectric layer 162. In some embodiments, the dummy gate electrode layer 164 may include polycrystalline-silicon (poly-Si), poly-crystalline silicon-germanium (poly-SiGe), metallic nitrides, metallic silicides, metallic oxides, or metals. In some embodiments, the dummy gate electrode layer 164 includes a metal-containing material such as TiN, TaN, TaC, Co, Ru, Al, combinations thereof, or multi-layers thereof. The dummy gate electrode layer 164 may be deposited by CVD, physical vapor deposition (PVD), sputter deposition, or other techniques suitable for depositing conductive materials.

Subsequently, dielectric layers 166 and 168 are formed on the dummy gate electrode layer 164 in sequence. In some embodiments, the dielectric layer 168 may be made of a different material than the dielectric layer 166. In some embodiments, the dielectric layer 166 may be made of a nitrogen-containing material, and the dielectric layer 168 may be made of a nitrogen-free material. By way of example and not limitation, the dielectric layer 166 may be made of a silicon carbo-nitride (SiCN), and the dielectric layer 168 may be made of silicon oxide (SiO₂). In some embodiments, the dielectric layer 166 may be made of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multi-layer structure including a plurality of dielectric layers. In some embodiments, the dielectric layer 168 may be made of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multi-layer structure including a plurality of dielectric layers.

Subsequently, a patterned mask layer (not shown) is formed over the dielectric layer 168 and then patterned to form separated mask portions over the first and second device regions 102 and 104. The patterned mask layer may be formed by a series of operations including deposition, photolithography patterning, and etching processes. The photolithography patterning processes may include photoresist coating (e.g., spin-on coating), soft baking, mask aligning, exposure, post-exposure baking, developing the photoresist, rinsing, drying (e.g., hard baking), and/or other applicable processes. The etching processes may include dry etching, wet etching, and/or other etching methods (e.g., reactive ion etching). One or more etching processes are performed to form dummy gate structures 160a wrapping around the semiconductor stack 120a and the protrusion structures 112a, and dummy gate structures 160b wrapping around the semiconductor stack 120b and the protrusion structures 112b using the patterned mask as an etching mask, and the patterned mask layer may be removed after the etching. The dummy gate structures 160a and 160b have substantially parallel longitudinal axes that are substantially perpendicular to a longitudinal axis of the semiconductor stack 120a and 120b. The dummy gate structures 160a and 160b will be replaced with a replacement gate structure using a “gate-last” or replacement-gate process. In some embodiments, the dummy gate structures 160a and 160b can be interchangeably referred to gates, gate patterns, gate strips.

Reference is made to FIGS. 12A-12D. After formation of the dummy gate structures 160 is completed, gate spacers 172 are formed on sidewalls of the dummy gate structures 160a and 160b and sidewall spacers 174 are formed on sidewalls of the semiconductor stack 120a and 120b. Specifically, a dielectric film can be deposited on the structure as illustrated in FIG. 11. The dielectric film may be silicon nitride (SiN), silicon carbonoxide (SiCO), silicon carbonnitride (SiCN), silicon oxycarbonnitride (SiOCN), or the like. The dielectric film can be conformally formed on the substrate 110, the dummy gate structures 160a and 160b, and the fin structures F1 and F2. In some embodiments, the dielectric film may be a single layer or multiple layers.

Subsequently, an anisotropic etching process is then performed on the deposited dielectric film to expose portions of the fin structures F1 and F2 not covered by the dummy gate structures 160a and 160b (e.g., in source/drain regions of the fin structures F1). Portions of the dielectric materials directly above the dummy gate structures 160a and 160b may be completely removed by this anisotropic etching process. Portions of the dielectric materials on sidewalls of the dummy gate structures 160a and 160b may remain, forming gate sidewall spacers, which are denoted as the gate spacers 172, for the sake of simplicity. Further, sidewall spacers 174, which are remaining parts of the dielectric film that are not removed in the operation of the anisotropic etching process, exist. Specifically, when the dielectric film is etched to form the gate spacers 172, portions of the dielectric film on sidewalls of the fin structures F1 and F2 are pullback-etched. Portions of the dielectric film thus remain at corners between the isolation structure 150 and the fin structures F1 and F2 after the etching and form the sidewall spacers 174. By way of example and not limitation, the gate spacer 172 may have a lateral dimension D21 (or width) in a range from about 1 to 10 nm, such as about 1, 2, 3, 4, 5, 6, 7, 8, 9, or 10 nm. The gate spacer 172 may have a vertical dimension D22 (or height) in a range from about 3 to 15 nm, such as about 3, 4, 5, 6, 7, 8, 9, 10, 11, 12, 13, 14, or 15 nm.

In some embodiments, the anisotropic etching may be performed by a dry chemical etch with a plasma source and a reaction gas. The plasma source may be an inductively coupled plasma (ICP) source, a transformer coupled plasma (TCP) source, an electron cyclotron resonance (ECR) source or the like, and the reaction gas may be, for example, a fluorine-based gas (such as SF₆, CH₂F2, CH₃F, CHF₃, or the like), chloride-based gas (e.g., Cl₂), hydrogen bromide gas (HBr), oxygen gas (O₂), the like, or combinations thereof.

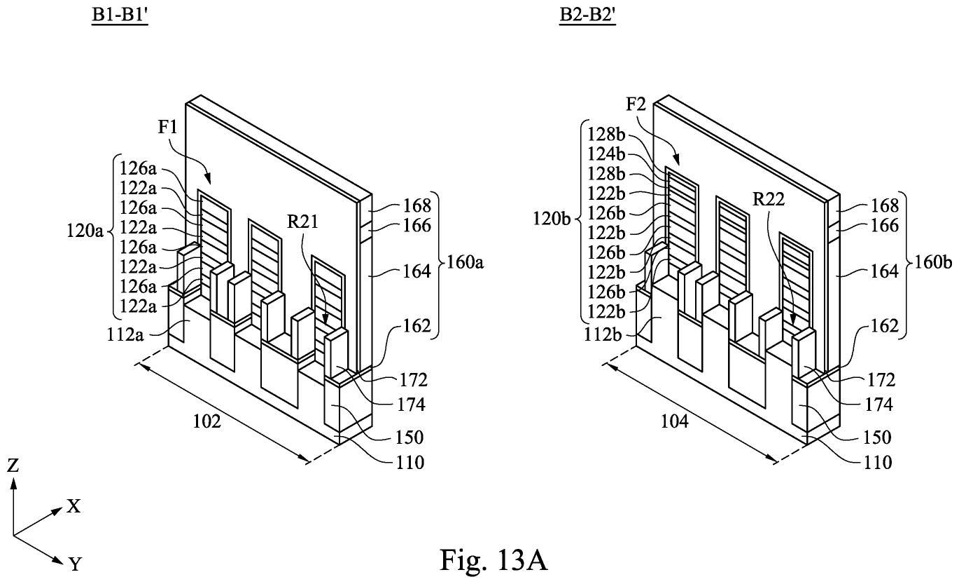

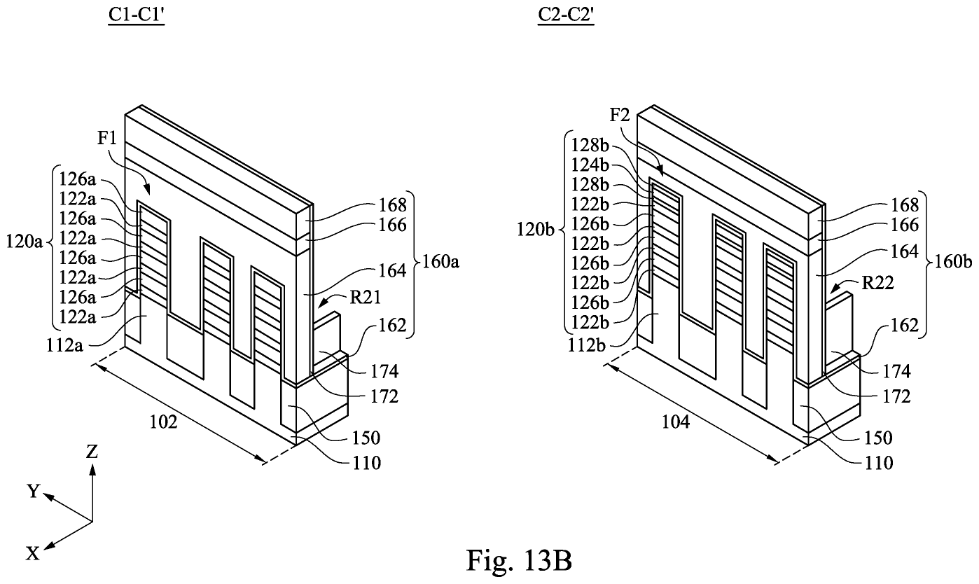

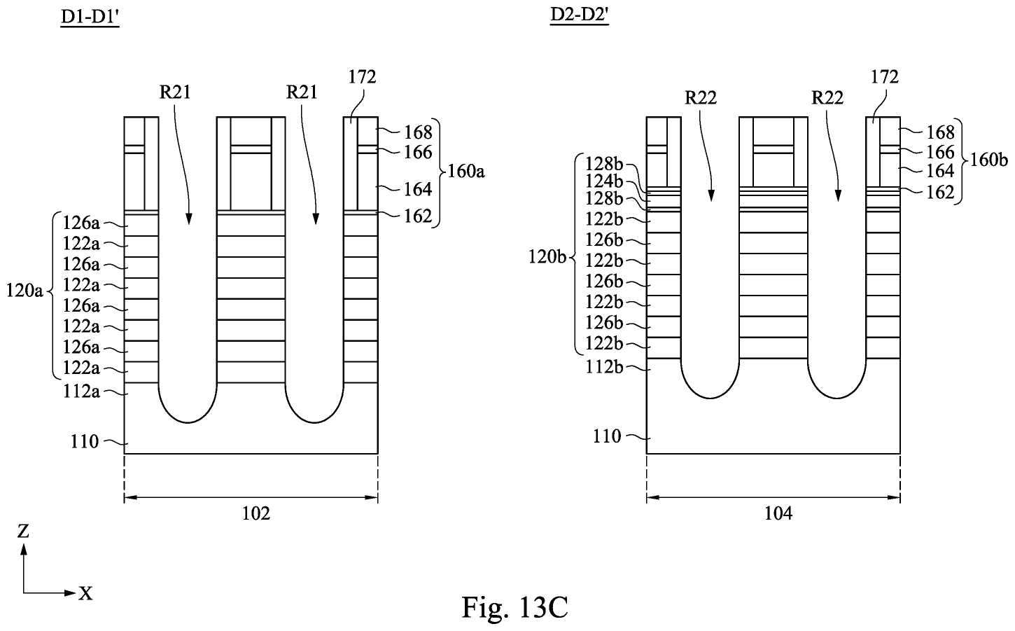

Reference is made to FIGS. 13A-13C. An anisotropic etching process may etch exposed portions of the fin structures F1 and F2 that extend laterally beyond the gate spacers 172 (e.g., in the source/drain regions of the fin structures F1), resulting in recesses R21 into the fin structures F1 and between corresponding dummy gate structures 160a, and recesses R22 into the fin structures F2 and between corresponding dummy gate structures 160b. After the anisotropic etching, end surfaces of the semiconductor layers 122a, 126a, 122b, 124b, 126b, and 128b are aligned with respective outermost sidewalls of the gate spacers 172, due to the anisotropic etching. In some embodiments, the protrusion structures 112a and 112b are also recessed.

In some embodiments, the anisotropic etching may be performed by a dry chemical etch with a plasma source and a reaction gas. The plasma source may be an inductively coupled plasma (ICP) source, a transformer coupled plasma (TCP) source, an electron cyclotron resonance (ECR) source or the like, and the reaction gas may be, for example, a fluorine-based gas (such as SF₆, CH₂F2, CH₃F, CHF₃, or the like), chloride-based gas (e.g., Cl₂), hydrogen bromide gas (HBr), oxygen gas (O₂), the like, or combinations thereof.

Reference is made to FIGS. 14A-14C. The semiconductor layers 122a over the first device region 102 are laterally or horizontally recessed by using suitable etch techniques, resulting in lateral recesses R31 each vertically between corresponding semiconductor layers 126a. In addition, the semiconductor layers 122b and 124b over the second device region 104 are laterally or horizontally recessed by using suitable etch techniques, resulting in lateral recesses R32 vertically between corresponding semiconductor layers 126b and a space S3 over the semiconductor layers 122b and 126b.

This operation may be performed by using a selective etching process. By way of example and not limitation, the semiconductor layers 122a, 122b, 124b are SiGe and the semiconductor layers 126a and 126b are silicon allowing for the selective etching of the semiconductor layers 122a, 122b, 124b. In some embodiments, the selective dry etching etches SiGe at a faster etch rate than it etches Si. As a result, the semiconductor layers 126a and 126b laterally extend past opposite end surfaces of the semiconductor layers 122a, 122b. In addition, since the epitaxial layer 124b (see FIGS. 13A-13C) over the second device region 104 has a greater germanium atomic concentration than the semiconductor layers 122a and 122b, the selective dry etching etches the epitaxial layer 124b at a faster etch rate than it etches the semiconductor layers 122a, 122b, and thus the semiconductor layer 124b can be completely removed while the semiconductor layers 122a, 122b can be only partially removed. Because of this thin thickness of the semiconductor layer 128b, it doesn't offer much resistance during the selective etching process on the semiconductor layer 124b. As a result, the thin semiconductor layer 128b is also consumed during the selective etching process. This simultaneous consumption of both layers 124b and 128b contributes to the formation of the space S3.

Subsequently, inner dielectric spacers 142a and 142b are formed in the recesses R31 and R32, and a helmet structure 144b is formed in the space S3. For example, a dielectric material are formed to fill the recesses R31 and R32 and the space S3 left by the lateral etching of the semiconductor layers 122a, 122b, 126b, and 128b discussed above. The dielectric material may be a low-k dielectric material, such as SiO₂, SiN, SiC, SiON, SiCN, or SiOCN, and may be formed by a suitable deposition method, such as ALD. In some embodiments, the dielectric material is intrinsic or un-doped with impurities. The dielectric material can be formed using CVD, including LPCVD and PECVD, PVD, ALD, or other suitable processes. After the deposition of the dielectric material, an anisotropic etching process may be performed to trim the deposited dielectric material, such that portions of the deposited dielectric material that fill the recesses R31 and R32 and the space S3 left by the lateral etching of the semiconductor layers 122a, 122b, 126b, and 128b are left. After the trimming process, the remaining portions of the deposited dielectric material are denoted as the dielectric spacers 142a and 142b in the recesses R31 and R32 and the helmet structure 144b in the space S3. The inner dielectric spacers 142a and 142b serve to isolate metal gates from source/drain epitaxial structures formed in subsequent processing. In some embodiments, the helmet structure 144b may have a lateral dimension D31 (or width) in a range from about 5 to 100 nm, such as about 5, 10, 20, 30, 40, 50, 60, 70, 80, 90, or 100 nm. The helmet structure 144b may have a vertical dimension D32 (or height) in a range from about 3 to 30 nm, such as about 3, 5, 10, 15, 20, 25, or 30 nm. In some embodiments, the helmet structure 144b can be interchangeably referred to as a dielectric helmet layer.

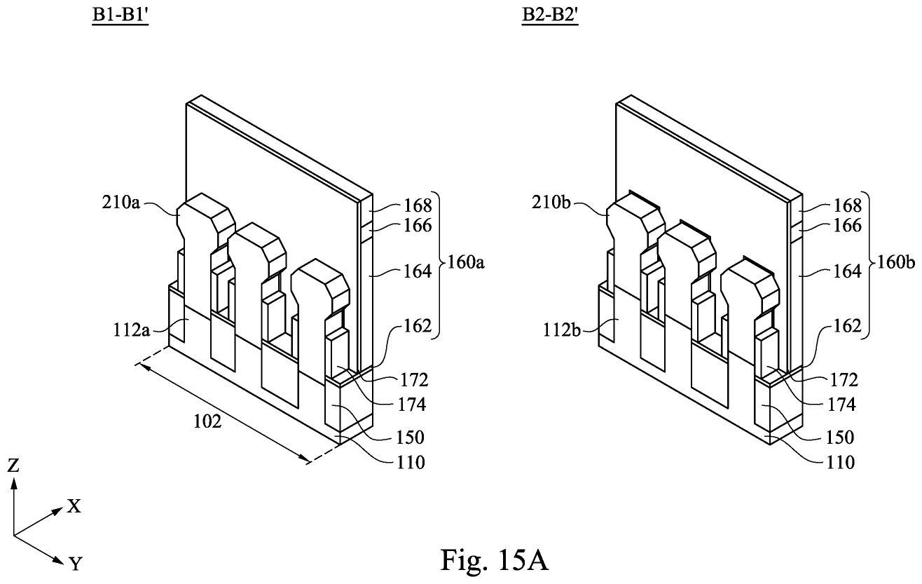

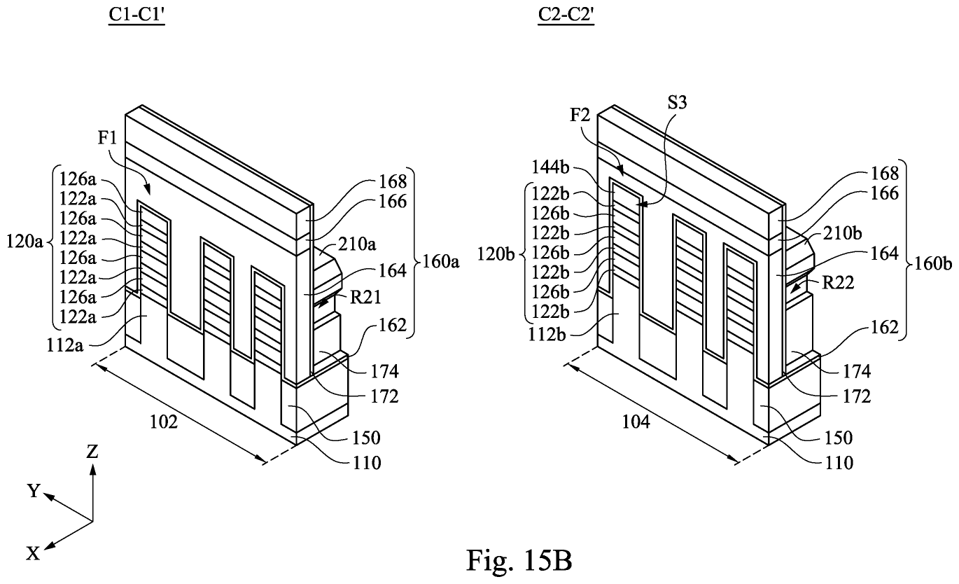

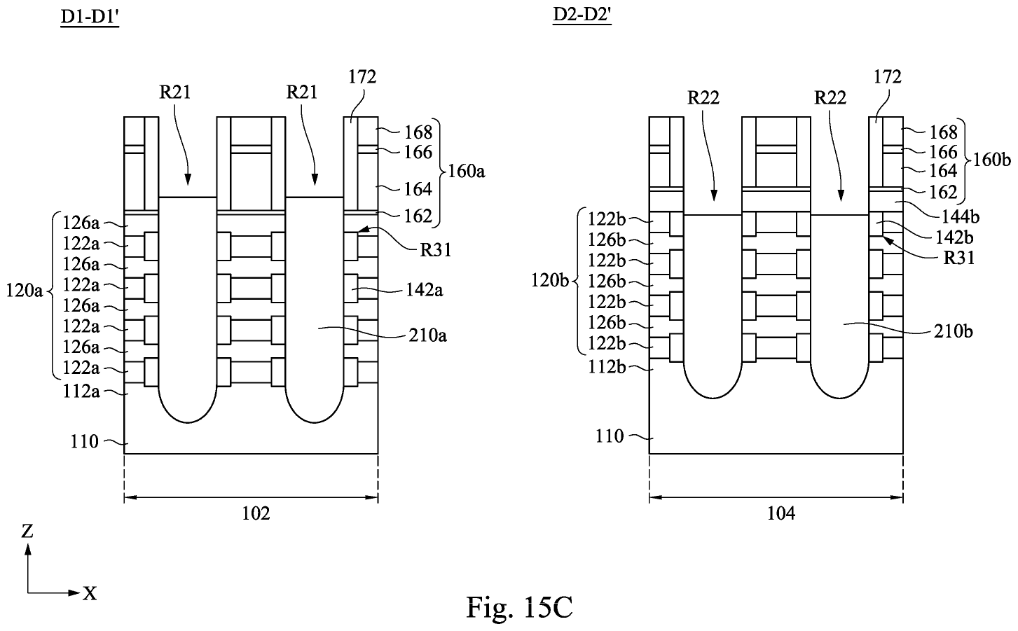

Reference is made to FIGS. 15A-15C. Source/drain epitaxial structures 210a are selectively grown on the protrusion structures 112a and the semiconductor layers over the first device region 102, and source/drain epitaxial structures 210b are selectively grown on the protrusion structures 112b and the semiconductor layers 124b over the second device region 104. The source/drain epitaxial structures 210a and 210b may be formed by performing an epitaxial growth process that provides an epitaxial material connected to the fin structures F1 and F2. During the epitaxial growth process, the dummy gate structures 160a and 160b, the gate spacers 172, the sidewall spacers 174 limit the source/drain epitaxial structures 210a and 210b to the source/drain regions. In some embodiments, the lattice constants of the source/drain epitaxial structures 210a and 210b are different from the lattice constant of the semiconductor layers 124a and 124b, so that the semiconductor layers 124a and 124b can be strained or stressed by the source/drain epitaxial structures 210a and 210b to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor layers 124a and 124b.

In some embodiments, the source/drain epitaxial structures 210a and 210b may include Ge, Si, GaAs, AlGaAs, SiGe, GaAsP, SiP, or other suitable material. The source/drain epitaxial structures 210a and 210b may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 210 are not in-situ doped, an implantation process (i.e., a junction implant process) is performed to dope the source/drain epitaxial structures 210a and 210b. In some embodiments, the source/drain epitaxial structures 210a and 210b can be interchangeably referred to as source/drain regions, source/drain patterns, or source/drain structures.

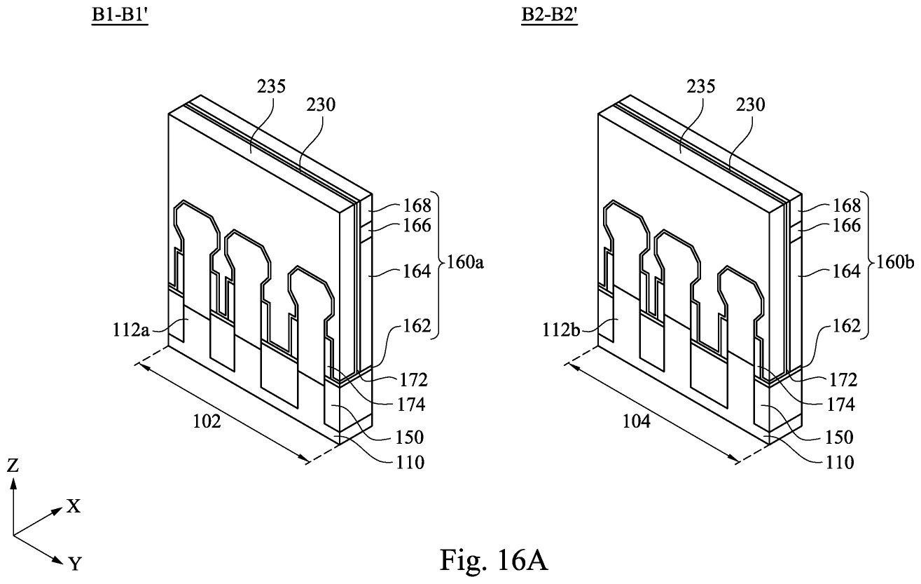

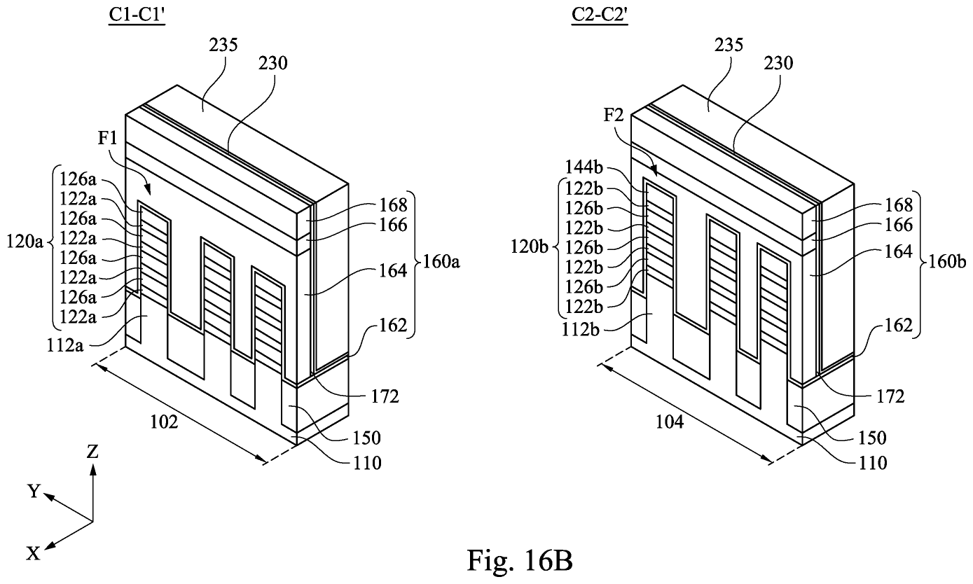

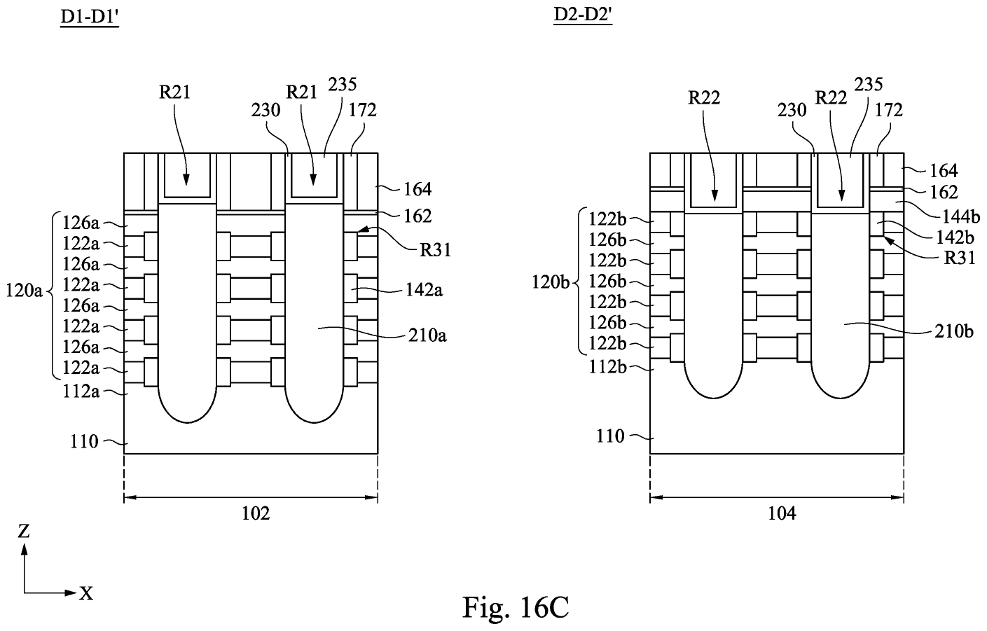

Reference is made to FIGS. 16A-16C. A contact etch stop layer (CESL) 230 is conformally formed over the first and second device regions 102 and 104 of the substrate 110. In some embodiments, the CESL 230 can be a stressed layer or layers. In some embodiments, the CESL 230 has a tensile stress and is formed of SiN, SiCN, combinations thereof, of the like. In some other embodiments, the CESL 230 includes materials such as oxynitrides. In yet some other embodiments, the CESL 230 may have a composite structure including a plurality of layers, such as a silicon nitride layer overlying a silicon oxide layer. The CESL 230 can be formed using plasma enhanced CVD (PECVD), however, other suitable methods, such as low-pressure CVD (LPCVD), atomic layer deposition (ALD), and the like, can also be used.

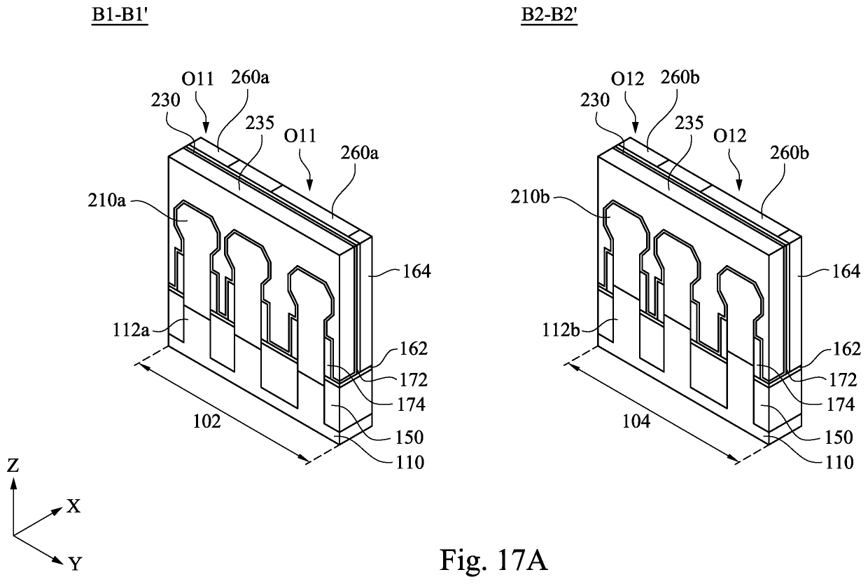

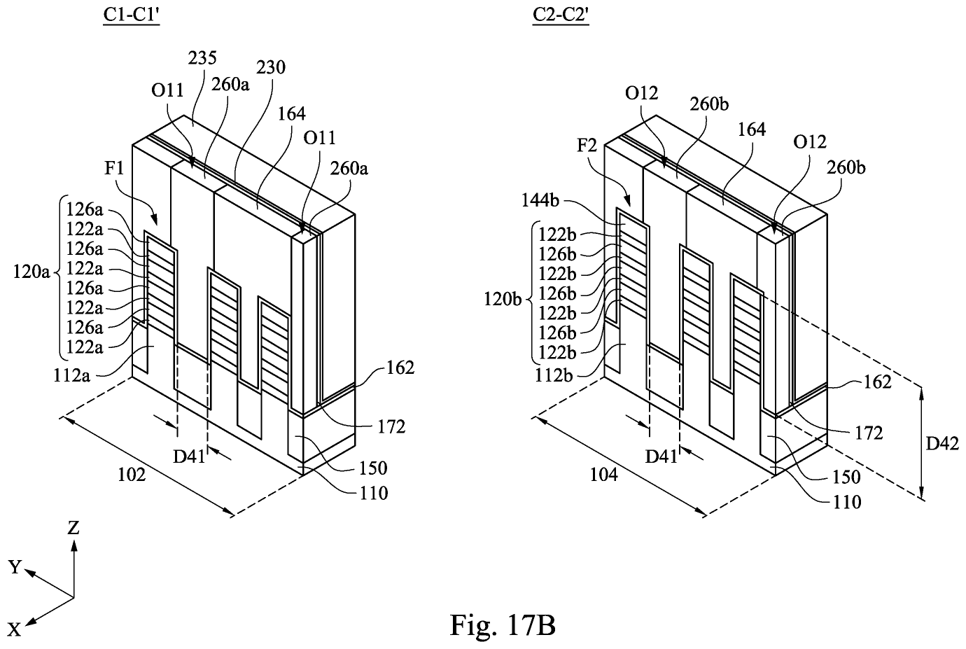

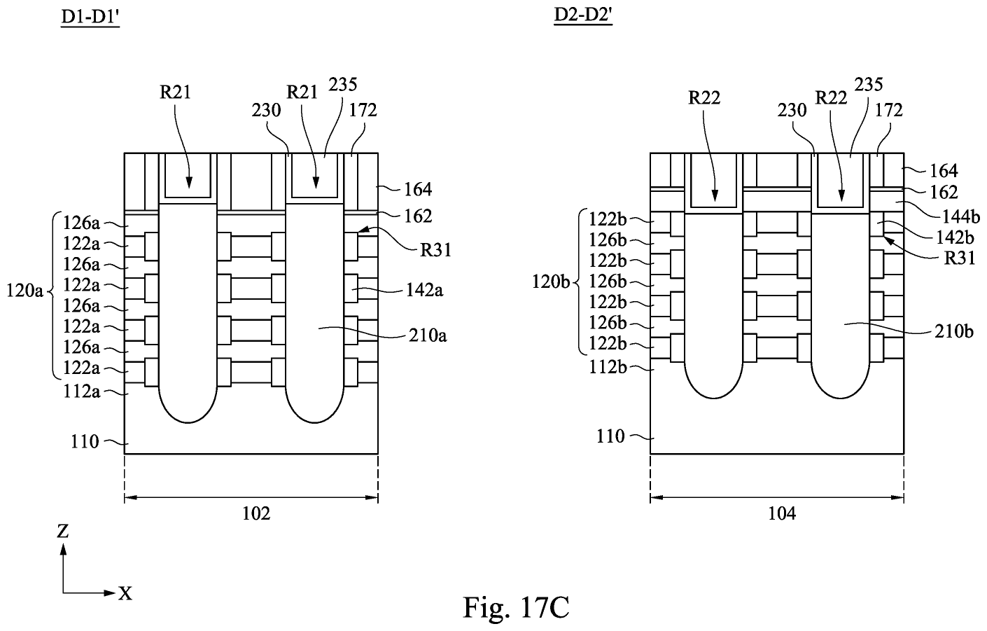

Subsequently, an interlayer dielectric (ILD) layer 235 is then formed on the CESL 230. The ILD layer 235 may be formed by chemical vapor deposition (CVD), high-density plasma CVD, spin-on, sputtering, or other suitable methods. In some embodiments, the ILD layer 235 includes silicon oxide. In some other embodiments, the ILD layer 235 may include silicon oxy-nitride, silicon nitride, SiOCN, compounds including Si, O, C and/or H (e.g., silicon oxide, SiCOH and SiOC), a low-k material, or organic materials (e.g., polymers). After the ILD layer 235 is formed, a planarization operation, such as CMP, is performed, so that the dielectric layers 166 and 168 (see FIGS. 17A-17C) are removed and the dummy gate electrode layers 164 are exposed.

Reference is made to FIGS. 17A-17C. Dielectric wall formations 260a are formed to separate the dummy gate structures 160a over the first device region 102, and the dielectric wall formations 260b are formed to separate the dummy gate structures 160b over the second device region 104. Specifically, an opening O11 is formed between the fin structures F1 and extend from a top surface of the dummy gate structures 160a to the isolation structures 150 to separate the dummy gate structures 160a. In addition, an opening O12 is formed between the fin structures F2 and extend from a top surface of the dummy gate structures 160b to the isolation structures 150 to separate the dummy gate structures 160b. Subsequently, a dielectric material are formed over the substrate 110 fills in the openings O11 and O12, and then a planarization process (e.g., CMP process) is performed to remove portions of the dielectric material outside the openings to form the dielectric wall formations 260a and 260b. In some embodiments, the formation of one or some of the dielectric wall formations 260a and 260b can be omitted (see FIG. 21D). In some embodiments, the dielectric wall formations 260a and 260b may include low-k materials such as silicon nitride (SiN), silicon oxide (SiO₂), silicon carbo-nitride (SiCN), silicon oxynitride (SiON), silicon oxy-carbo-nitride (SiOCN), the like, and/or other suitable dielectric materials. By way of example and not limitation, the dielectric wall formation 260a/260b may have a lateral dimension D41 (or width) in a range from about 15 to 150 nm, such as about 15, 20, 30, 40, 50, 60, 70, 80, 90, 100, 110, 120, 130, 140, or 150 nm. The dielectric wall formation 260a/260b may have a vertical dimension D42 (or height) in a range from about 20 to 200 nm, such as about 20, 40, 60, 80, 100, 120, 140, 160, 180, or 200 nm.

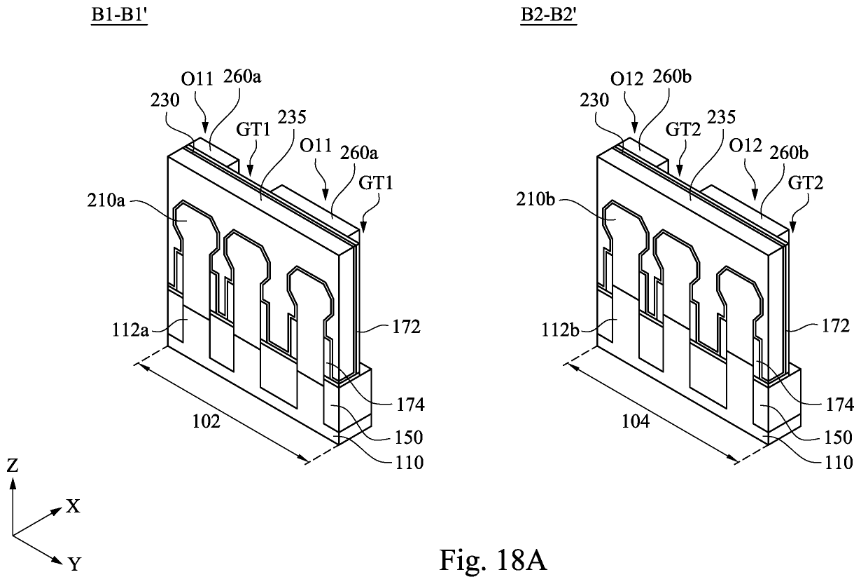

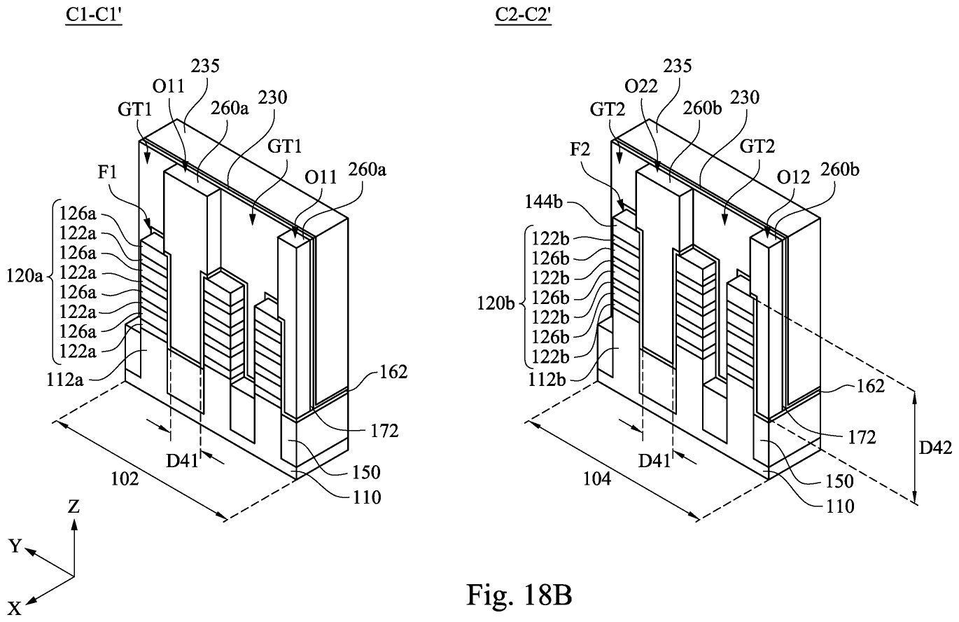

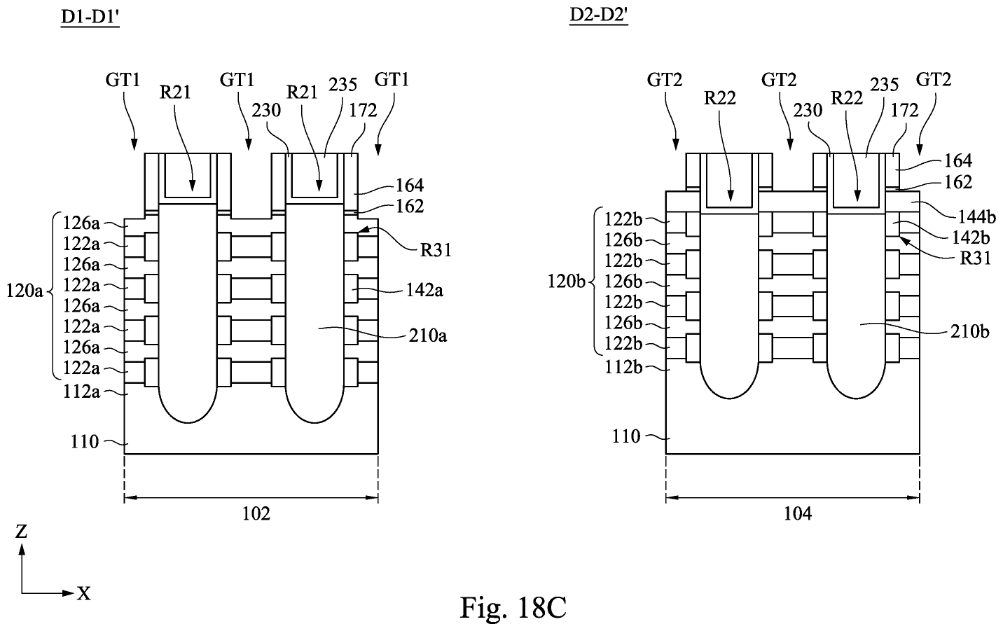

Reference is made to FIGS. 18A-18C. The dummy gate electrode layers 164 and the dummy gate dielectric layers 162 of the dummy gate structures 160a and 160b (see FIGS. 17A-17C) are then removed, thereby exposing the semiconductor layers 122a, 124a, 122b, and 124b. The ILD layer 235 protects the source/drain epitaxial structures 210a and 210b during the removal of the dummy gate electrode layers 164 and the dummy gate dielectric layers 162. In some embodiments, the dummy gate electrode layers 164 and the dummy gate dielectric layers 162 are removed by using a selective etching process (e.g., selective dry etching, selective wet etching, or combinations thereof) that etches the materials in dummy gate electrode layers 164 and the dummy gate dielectric layers 162 at a faster etch rate than it etches other materials (e.g., the gate spacers 172 and/or the ILD layer 235), thus resulting in gate trenches GT1 between corresponding gate spacers 172, with the semiconductor layers 122a and 124a exposed in the gate trenches GT1, and gate trenches GT2 between corresponding gate spacers 172, with the semiconductor layers 122b and 124b exposed in the gate trenches GT2.

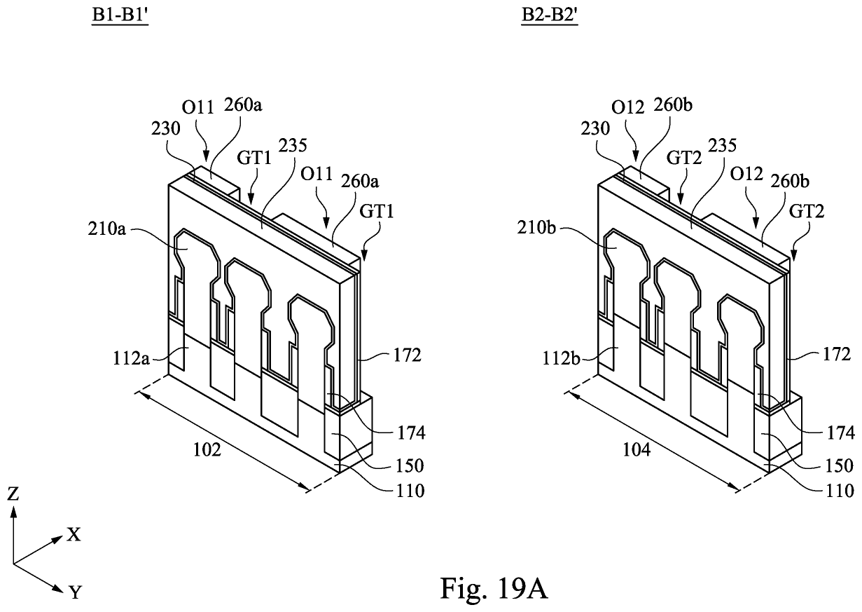

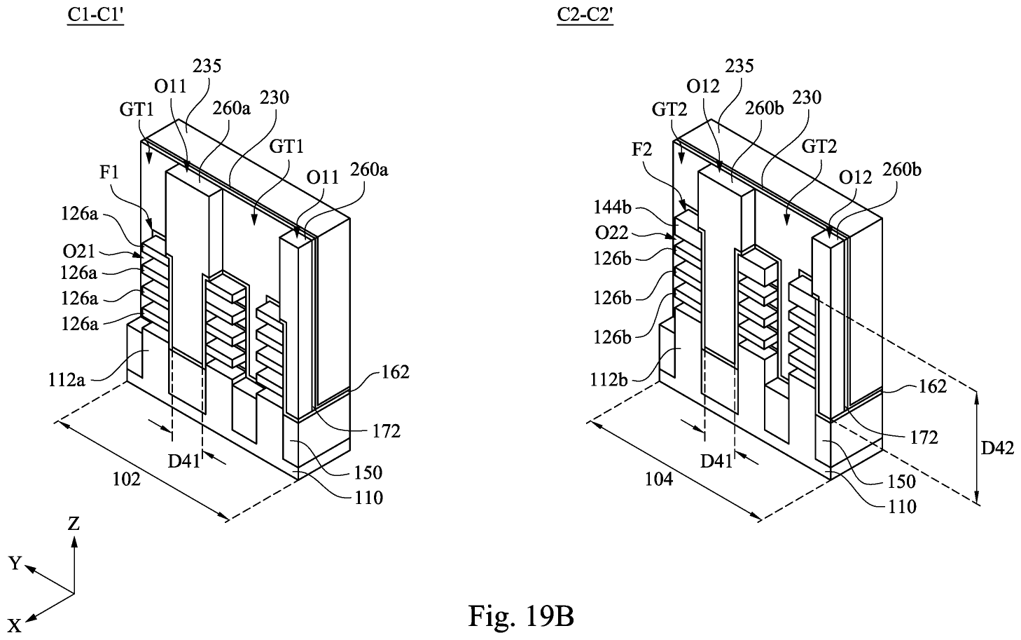

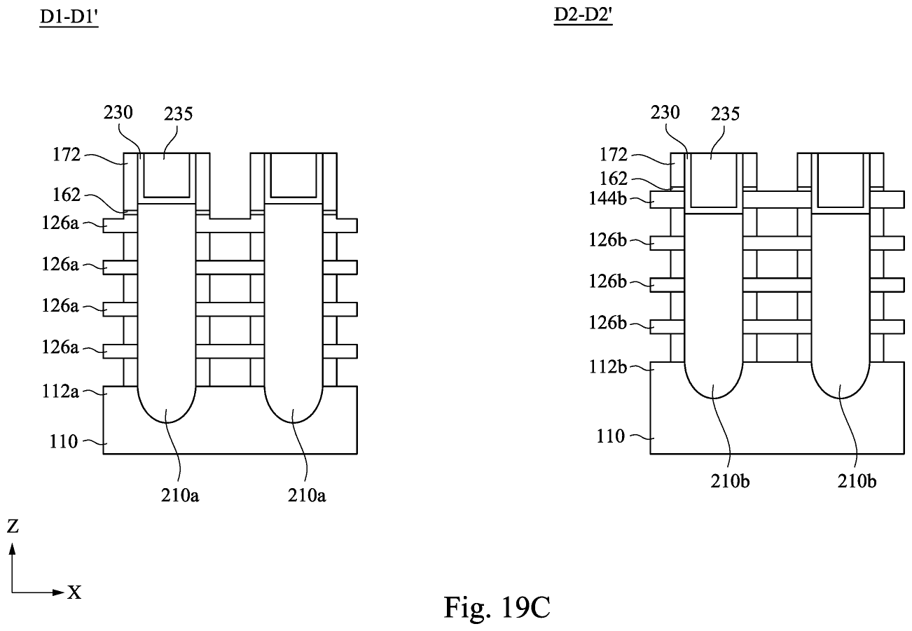

Reference is made to FIGS. 19A-19C. Subsequently, the semiconductor layers 122a in the gate trenches GT1 and the semiconductor layers 122b in the gate trenches GT2 are removed by using another selective etching process that etches the semiconductor layers 122a and 122b at a faster etch rate than it etches the semiconductor layers 124a and 124b, thus forming openings O21 between neighboring semiconductor layers (i.e., channel layers) 124a and openings O22 between neighboring semiconductor layers (i.e., channel layers) 124b. In this way, the semiconductor layers 124a and 124b become nanosheets suspended over the substrate 110 and between the source/drain epitaxial structures 210a and 210b. This operation is also called a channel release process. In some embodiments, the semiconductor layers 124a and 124b can be interchangeably referred to as nanostructure (fork-sheets, nanowires, nanoslabs and nanorings, nanosheet, etc., depending on their geometry). For example, in some other embodiments the semiconductor layers 124a and 124b may be trimmed to have a substantial rounded shape (i.e., cylindrical) due to the selective etching process for completely removing the semiconductor layers 122a and 122b. In that case, the resultant semiconductor layers 124a and 124b can be called nanosheet.

In some embodiments, the stack of the semiconductor layers 124a can be interchangeably referred to a first nanosheet stack, and the stack of the semiconductor layers 124b can be interchangeably referred to a second nanosheet stack. A number of the semiconductor layers 124b in the second nanosheet stack is different than a number of the semiconductor layers 124a in the first nanosheet stack. In some embodiments, the number of the semiconductor layers 124b in the second nanosheet stack is 1 to 3 more than the number of the semiconductor layers 124a in the first nanosheet stack. By way of example and not limitation, the number of the semiconductor layers 124a in the first nanosheet stack within the first device region 102 can be in a range from about 1 to 15, such as 1, 2, 3, 4, 5, 6, 7, 8, 9, 10, 11, 12, 13, 14, or 15. The number of the semiconductor layers 124b in the second nanosheet stack within the second device region 104 can be in a range from about 1 to 15, such as 1, 2, 3, 4, 5, 6, 7, 8, 9, 10, 11, 12, 13, 14, or 15.

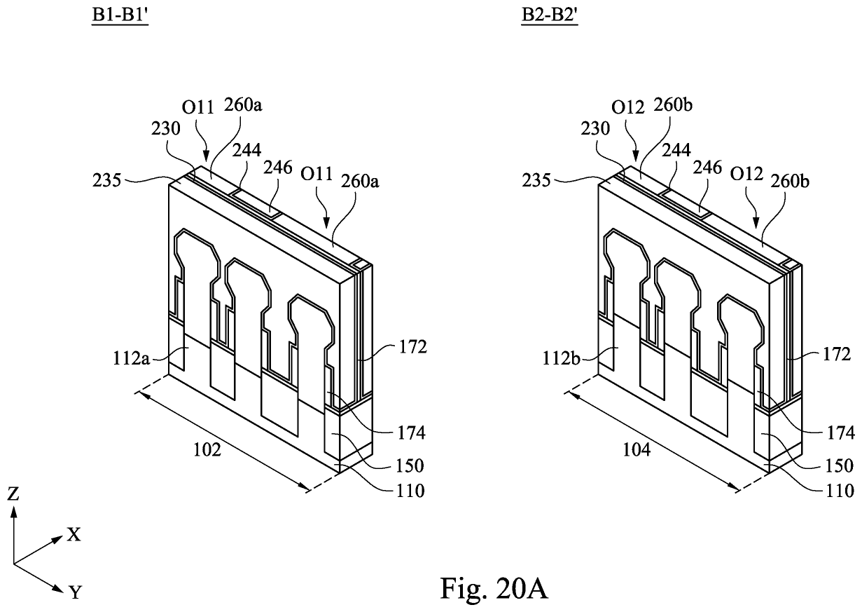

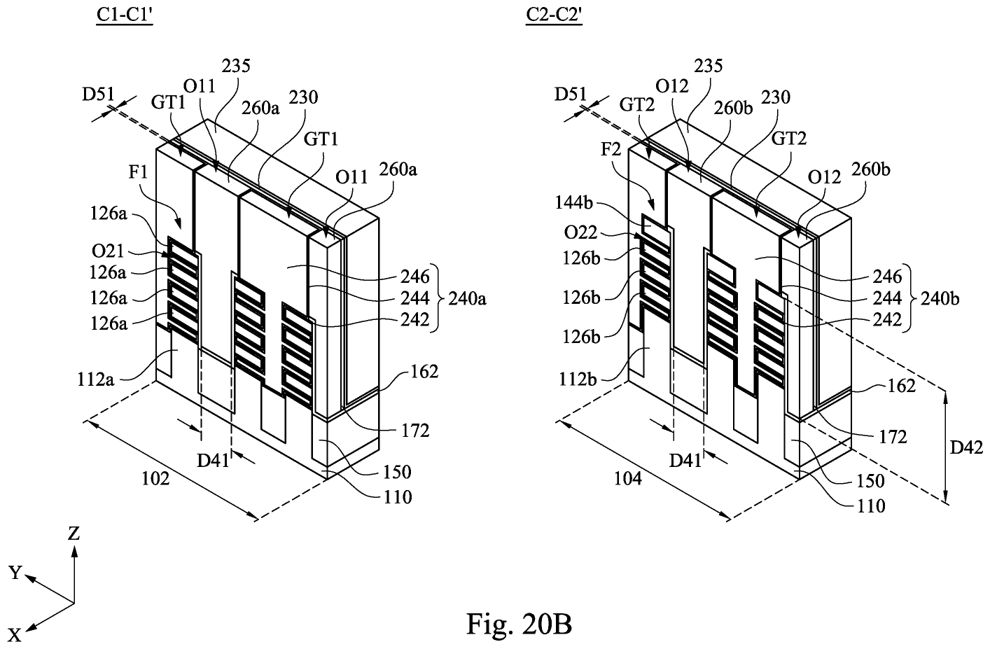

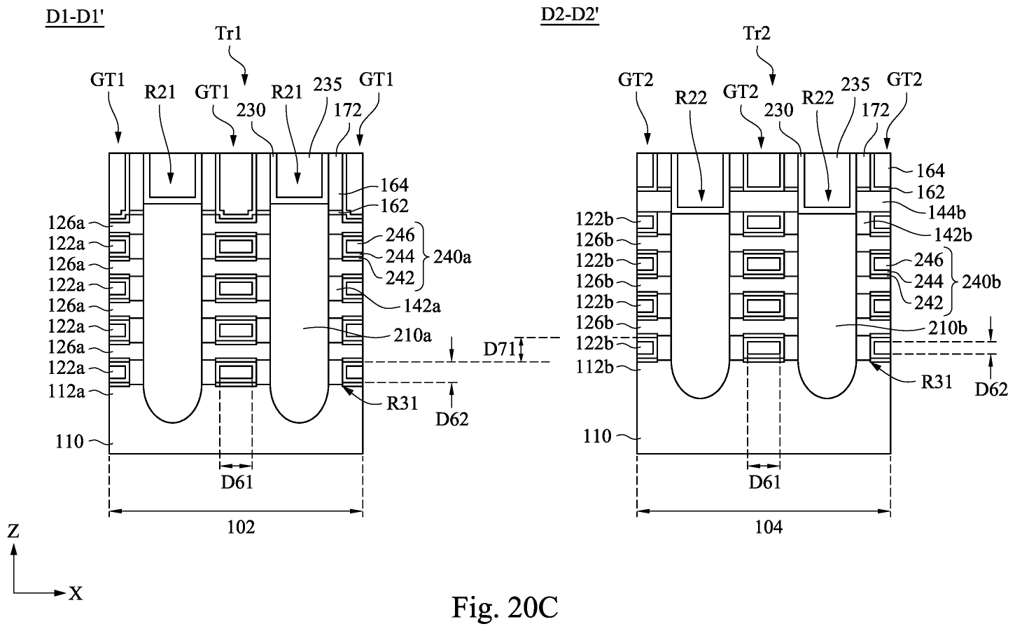

Reference is made to FIGS. 20A-20C. An interfacial layer 242 (see FIGS. 20B and 20C) is formed in the gate trenches GT1 and GT2 and the openings O21 and O22 and around the semiconductor layers 124a and 124b. In some embodiments, the interfacial layer 242 may include a dielectric material such as silicon oxide (SiO₂), HfSiO, or silicon oxynitride (SiON). The interfacial layer 242 may be formed by chemical oxidation, thermal oxidation, atomic layer deposition (ALD), chemical vapor deposition (CVD), and/or other suitable method. In some embodiments, the interfacial layer 242 can be interchangeably referred to an oxide layer.

Subsequently, a gate dielectric layer 244 is formed over the interfacial layer 242. In addition, the gate dielectric layer 244 is formed over the interfacial layer 242. The gate dielectric layer 244 may include dielectric materials having a high dielectric constant, for example, greater than that of thermal silicon oxide (˜3.9). For example, the gate dielectric layer 244 may include hafnium oxide (HfO₂). Alternatively, the gate dielectric layer 244 may include other high-k dielectrics, such as hafnium silicon oxide (HfSiO), HfAlxOy, hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. By way of example and not limitation, the gate dielectric layer 244 may have a vertical dimension D51 (or thickness) in a range from about 0.5 to 3 nm, such as about 0.5, 1, 1.5, 2, 2.5, or 3 nm.

Subsequently, a work function metal layer 246 is formed around the gate dielectric layer 244 and fills the gate trenches GT1 and GT2 and the openings O1 and O2. In some embodiments, the work function metal layer 246 may include a single layer or multi layers. In some embodiments, the work function metal layer 246 can be a P-type work function metal layer or an N-type work function metal layer. By way of example and not limitation, the work function metal layer 246 may include Ti, TiAl, TiAl(Si)C, TiAlC, TiSiAlC, TiAlN, TiSiN, TaC, TaCN, TaSiN, Mn, Zr, TiN, TaN, TSN, Ru, Mo, WN, WCN, Co, Al, or any suitable materials. The work function metal layer 246 may be formed by ALD, PVD, CVD, or other suitable process. As shown in FIG. 20C, a bottom of the work function metal layer 246 within the second device region 104 is vertically offset from a bottom of the work function metal layer 246 within the first device region 102. By way of example and not limitation, the work function metal layer 246 may have a lateral dimension D61 (or width) in a range from about 5 to 100 nm, such as about 5, 10, 20, 30, 40, 50, 60, 70, 80, 90, or 100 nm. The work function metal layer 246 may have a vertical dimension D62 (or height) between adjacent two the semiconductor layers 124a/124b in a range from about 3 to 25 nm, such as about 3, 5, 10, 15, 20, or 25 nm. In some embodiments, the work function metal layer 246 can be interchangeably referred to as a filling metal, a gate electrode layer, or a gate metal. Therefore, gate structures 240a are formed over the first device region 102, and gate structures 240b are formed over the second device region 104. Each of the gate structures 240a and 240b may include interfacial layer 242, the high-k gate dielectric layer 244, and the work function metal layer 246. The gate structure 240a/240b can be interchangeably referred to as a gate strip, a gate pattern, a gate layer, a metal gate, or a gate. Therefore, transistors (or nanostructure devices) Tr1 (see FIG. 20C) are formed over the first device region 102, and transistors (or nanostructure devices) Tr2 (see FIG. 20C) are formed over the second device region 104. The transistors Tr1 can be N-type transistors and/or P-type transistors, and the transistors Tr2 can be N-type transistors and/or P-type transistors. The transistor Tr1 can include the semiconductor layers 124a as channel regions, the gate structures 240a around the semiconductor layers 124a, and a pair of the source/drain epitaxial structures 210a on opposite sides of each of the semiconductor layers 124a, and the transistor Tr2 can include the semiconductor layers 124b as channel regions, the gate structures 240b around the semiconductor layers 124b, and a pair of the source/drain epitaxial structures 210b on opposite sides of each of the semiconductor layers 124a.

As shown FIG. 20C, a lowermost one of the semiconductor layers 124b is vertically offset from a lowermost one of the semiconductor layers 124a by a non-zero distance. For example, a lowermost one of the semiconductor layers 124b within the second device region 104 can be in a higher position level than a lowermost one of the semiconductor layers 124a within the first device region 102, at about a vertical dimension D71 in a range from about 5 to 30 nm, such as 5, 10, 15, 20, 25, or 30 nm.

Reference is made to FIGS. 21A-21C and 21E. After the transistors Tr1 and Tr2 are formed, a planarization operation, such as CMP, is performed, so that the dielectric wall formations 260a and 260b, the high-k gate dielectric layer 244, and the work function metal layer 246 (see FIGS. 20A-20C) over the helmet structure 144b are removed until the and the helmet structures 144b are exposed. As shown FIG. 21E, after the planarization operation, within the first device region 102, the gate spacers 172 surrounding the high-k gate dielectric layer 244 and the work function metal layer 246 is on a top of the stack of the semiconductor layers 124a. On the contrary, after the planarization operation, within the second device region 104, the helmet structure 144b is on a top of the stack of the semiconductor layers 124b. In some embodiments, a top surface of the helmet structure 144b can be level with a top surface of the gate spacer 172.

As shown FIG. 21E, a bottom of the source/drain epitaxial structure 210b is vertically offset from a bottom of the source/drain epitaxial structure 210a by a non-zero distance. For example, a bottom of the source/drain epitaxial structure 210b within the second device region 104 can be in a higher position level than a bottom of the source/drain epitaxial structure 210a within the first device region 102, at about a vertical dimension D72 in a range from about 5 to 30 nm, such as 5, 10, 15, 20, 25, or 30 nm. In some embodiments, a vertical dimension of the source/drain epitaxial structure 210b is less than a vertical dimension of the source/drain epitaxial structure 210a.

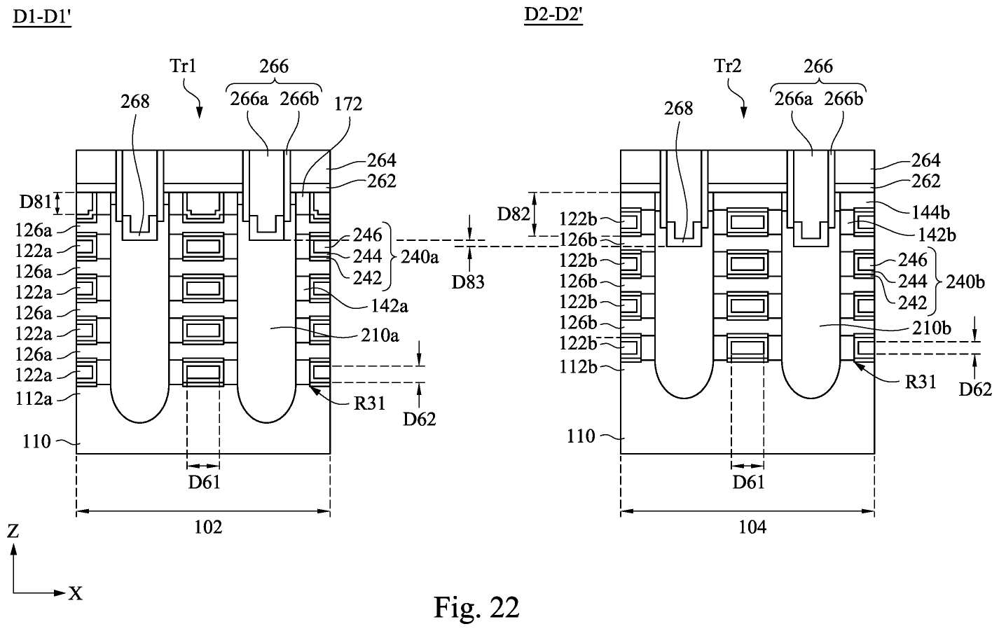

Reference is made to FIG. 22. A contact etch stop layer (CESL) 262 is conformally formed over the first and second device regions 102 and 104 of the substrate 110. In some embodiments, the CESL 262 can be a stressed layer or layers. In some embodiments, the CESL 262 has a tensile stress and is formed of SiN, SiCN, combinations thereof, of the like. In some other embodiments, the CESL 262 includes materials such as oxynitrides. In yet some other embodiments, the CESL 262 may have a composite structure including a plurality of layers, such as a silicon nitride layer overlying a silicon oxide layer. The CESL 262 can be formed using plasma enhanced CVD (PECVD), however, other suitable methods, such as low-pressure CVD (LPCVD), atomic layer deposition (ALD), and the like, can also be used. As shown FIG. 22, a topmost one of the semiconductor layers 124a and the CESL 262 has a distance D81 therebetween within the first device region 102, and a topmost one of the semiconductor layers 124b and the CESL 262 has a distance D82 therebetween within the second device region 104. In some embodiments, the distance D82 can be greater than the distance D81. By way of example and not limitation, the distance D81 may be in a range from about 3 to 15 nm, such as about 3, 4, 5, 6, 7, 8, 9, 10, 11, 12, 13, 14, or 15 nm. The distance D82 may be in a range from about 6 to 40 nm, such as about 6, 10, 15, 20, 25, 30, 35, or 40 nm.

Subsequently, an interlayer dielectric (ILD) layer 264 is then formed on the CESL 264. The ILD layer 264 may be formed by chemical vapor deposition (CVD), high-density plasma CVD, spin-on, sputtering, or other suitable methods. In some embodiments, the ILD layer 264 includes silicon oxide. In some other embodiments, the ILD layer 264 may include silicon oxy-nitride, silicon nitride, SiOCN, compounds including Si, O, C and/or H (e.g., silicon oxide, SiCOH and SiOC), a low-k material, or organic materials (e.g., polymers).

Subsequently, source/drain contacts 266 are formed in the CESL 264 and the ILD layer 264 and over the source/drain epitaxial structures 210a and 210b. The source/drain contacts 266 may include contact metal 266a and barrier layer 266b. In some embodiments, the source/drain silicide regions 268 can be formed between the source/drain contacts 266 and the source/drain epitaxial structures 210a and 210b. In some embodiments, materials of the source/drain contacts 266 may include Cu, Co, Ru, Pt, Al, W, Ti, TaN, TiN, or any combinations thereof. A bottom of the source/drain contact 266 within the second device region 104 can be in a deeper position level than a bottom of the source/drain contacts 266 within the first device region 102, at about a vertical dimension D83 in a range from about 1 to 25 nm, such as 1, 5, 10, 15, 20, or 25 nm. In some embodiments, a vertical dimension of the metal contact 266 within the second device region 104 is greater than a vertical dimension of the metal contact 266 within the first device region 102. In some embodiments, the source/drain contact 266 can be interchangeably referred to as a metal contact.

Reference is made to FIG. 21D. FIG. 21D is a cross-sectional view of a semiconductor structure 100a corresponding to FIG. 21C according to some embodiments of the present disclosure. While FIG. 21D show an embodiment of the semiconductor structure 100a with different channel cross-sectional view profile than the semiconductor structure 100 in FIGS. 1-21C, 21E, and 22. In addition, the present disclosure may repeat reference numerals and/or letters in the various examples. This repetition is for the purpose of simplicity and clarity and does not in itself dictate a relationship between the various embodiments and/or configurations discussed. As shown in FIG. 21D, the difference between the embodiment in FIG. 21D and the embodiment in FIGS. 1-21C, 21E, and 22 is in that the dielectric wall formations 260a and 260b as shown in FIG. 21C can be omitted.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method to incorporate multiple nanosheet stack structures on one wafer. By allowing different nanosheet stack structures on distinct areas of a single wafer, this disclosure facilitates a more tailored and efficient design, catering to the specific needs of different semiconductor regions. Different regions can now have transistors with characteristics best suited for their specific functions, potentially boosting overall device performance.

In some embodiments, a method includes forming first semiconductive sheets over a substrate and arranged in a vertical direction, and second semiconductive sheets over the substrate and arranged in the vertical direction, wherein a number of the second semiconductive sheets is different than a number of the first semiconductive sheets; forming first source/drain regions on either side of each of the first semiconductive sheets, and second source/drain regions on either side of each of the second semiconductive sheets; forming a first gate around each of the first semiconductive sheets, and a second gate around each of the second semiconductive sheets. In some embodiments, the number of the first semiconductive sheets is 1-3 more than the number of the second semiconductive sheets. In some embodiments, the method further includes forming a first protrusion structure protruding from the substrate and underlying the first semiconductive sheets, and a second protrusion structure protruding from the substrate and underlying the second semiconductive sheets, wherein a top surface of the second protrusion structure is in a higher position than a top surface of the first protrusion structure. In some embodiments, the method further includes forming a shallow trench isolation (STI) structure laterally surrounding lower portions of the first and second protrusion structures, wherein the top surface of the first protrusion structure and a top surface of the STI structure has a first distance therebetween, and the top surface of the second protrusion structure and the top surface of the STI structure has a second distance therebetween, the second distance is greater than the first distance. In some embodiments, the method further includes the first distance is 1 to 40 nm greater than the second distance. In some embodiments, a lowermost one of the second semiconductive sheets is vertically offset from a lowermost one of the first semiconductive sheets by a non-zero distance. In some embodiments, the non-zero distance is in a range from about 5 to 30 nm. In some embodiments, a bottom of the second gate is vertically offset from a bottom of the first gate. In some embodiments, a bottom of one of the second source/drain regions is vertically offset from a bottom of one of the first source/drain regions by a non-zero distance. In some embodiments, the method further includes forming a gate spacer over the first semiconductive sheets and on a sidewall of the first gate; forming a dielectric helmet layer over the second semiconductive sheets and covering the second gate, wherein a top surface of the dielectric helmet layer is level with a top surface of the gate spacer.

In some embodiments, a method includes forming a first device over a substrate, the first device including: a plurality of first channel patterns stacked in a vertical direction; a first gate pattern wrapping around the first channel patterns; and a plurality of first epitaxial patterns on either side of each of the first channel patterns; and forming a second device over the substrate, the second device including: a plurality of second channel patterns stacked in the vertical direction, wherein a lowermost one of the second channel patterns is in a higher position than a lowermost one of the first channel patterns, and an uppermost one of the second channel patterns is in a lower position than an uppermost one of the first channel patterns; a second gate pattern wrapping around the second channel patterns; and a plurality of second epitaxial patterns on either side of each of the second channel patterns. In some embodiments, a number of the second channel patterns is less than a number of the first channel patterns. In some embodiments, a bottom of the second gate pattern is in a higher position than a bottom of the first gate pattern. In some embodiments, a bottom of one of the second epitaxial patterns is in a higher position than a bottom of one of the first epitaxial patterns. In some embodiments, the method further includes forming a first fin strip protruding from the substrate and underlying the first channel patterns, and a second fin strip protruding from the substrate and underlying the second channel patterns, wherein a vertical dimension the second fin strip is greater than a vertical dimension of the first fin strip.

In some embodiments, the semiconductor structure includes a substrate, a first transistor, a second transistor, a first metal contact, and a second metal contact. The first transistor is over the substrate. The first transistor includes a plurality of first nanostructures arranged in a vertical direction, a plurality of first epitaxial structures on either side of each of the first nanostructures, and a first gate structure around the first nanostructures and between the first epitaxial structures. The second transistor is over the substrate. The second transistor includes a plurality of second nanostructures arranged in the vertical direction, wherein a number of the second nanostructures is less than a number of the first nanostructures, a plurality of second epitaxial structures on either side of each of the second nanostructures, and a second gate structure around the second nanostructures and between the second epitaxial structures. The first metal contact is over one of the first epitaxial structures. The second metal contact is over one of the second epitaxial structures, wherein a bottom of the second metal contact is deeper than a bottom of the first metal contact. In some embodiments, a vertical dimension of the second metal contact is greater than a vertical dimension of the first metal contact. In some embodiments, a vertical dimension of the one of the second epitaxial structures is less than a vertical dimension of the one of the first epitaxial structures. In some embodiments, the semiconductor structure further includes a contact etch stop layer over the first and second transistors, in which the first and second metal contacts pass through the contact etch stop layer, an uppermost one of the first nanostructures and the contact etch stop layer has a first distance therebetween, and an uppermost one of the second nanostructures and the contact etch stop layer has a second distance therebetween, the second distance is greater than the first distance. In some embodiments, the first distance is in a range from 3-15 nm, and the second distance is in a range from 6-40 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming first semiconductive sheets over a substrate and arranged in a vertical direction, and second semiconductive sheets over the substrate and arranged in the vertical direction, wherein a number of the second semiconductive sheets is different than a number of the first semiconductive sheets;
forming first source/drain regions on either side of each of the first semiconductive sheets, and second source/drain regions on either side of each of the second semiconductive sheets; and
forming a first gate around each of the first semiconductive sheets, and a second gate around each of the second semiconductive sheets.

2. The method of claim 1, wherein the number of the first semiconductive sheets is 1-3 more than the number of the second semiconductive sheets.

3. The method of claim 1, further comprising:
forming a first protrusion structure protruding from the substrate and underlying the first semiconductive sheets, and a second protrusion structure protruding from the substrate and underlying the second semiconductive sheets, wherein a top surface of the second protrusion structure is in a higher position than a top surface of the first protrusion structure.

4. The method of claim 3, further comprising:
forming a shallow trench isolation (STI) structure laterally surrounding lower portions of the first and second protrusion structures, wherein the top surface of the first protrusion structure and a top surface of the STI structure has a first distance therebetween, and the top surface of the second protrusion structure and the top surface of the STI structure has a second distance therebetween, the second distance is greater than the first distance.

5. The method of claim 4, wherein the first distance is 1 to 40 nm greater than the second distance.

6. The method of claim 1, wherein a lowermost one of the second semiconductive sheets is vertically offset from a lowermost one of the first semiconductive sheets by a non-zero distance.

7. The method of claim 5, wherein the non-zero distance is in a range from about 5 to 30 nm.

8. The method of claim 1, wherein a bottom of the second gate is vertically offset from a bottom of the first gate.

9. The method of claim 1, wherein a bottom of one of the second source/drain regions is vertically offset from a bottom of one of the first source/drain regions by a non-zero distance.

10. The method of claim 1, further comprising:
forming a gate spacer over the first semiconductive sheets and on a sidewall of the first gate; and
forming a dielectric helmet layer over the second semiconductive sheets and covering the second gate, wherein a top surface of the dielectric helmet layer is level with a top surface of the gate spacer.

11. A method, comprising:
forming a first device over a substrate, the first device comprising:
a plurality of first channel patterns stacked in a vertical direction;
a first gate pattern wrapping around the first channel patterns; and
a plurality of first epitaxial patterns on either side of each of the first channel patterns; and
forming a second device over the substrate, the second device comprising:
a plurality of second channel patterns stacked in the vertical direction, wherein a lowermost one of the second channel patterns is in a higher position than a lowermost one of the first channel patterns, and an uppermost one of the second channel patterns is in a lower position than an uppermost one of the first channel patterns;
a second gate pattern wrapping around the second channel patterns; and
a plurality of second epitaxial patterns on either side of each of the second channel patterns.

12. The method of claim 11, wherein a number of the second channel patterns is less than a number of the first channel patterns.

13. The method of claim 11, wherein a bottom of the second gate pattern is in a higher position than a bottom of the first gate pattern.

14. The method of claim 11, wherein a bottom of one of the second epitaxial patterns is in a higher position than a bottom of one of the first epitaxial patterns.

15. The method of claim 11, further comprising:
forming a first fin strip protruding from the substrate and underlying the first channel patterns, and a second fin strip protruding from the substrate and underlying the second channel patterns, wherein a vertical dimension the second fin strip is greater than a vertical dimension of the first fin strip.

16. A semiconductor structure, comprising:
a substrate;
a first transistor over the substrate, the first transistor comprising:
a plurality of first nanostructures arranged in a vertical direction;
a plurality of first epitaxial structures on either side of each of the first nanostructures; and
a first gate structure around the first nanostructures and between the first epitaxial structures;
a second transistor over the substrate, the second transistor comprising:
a plurality of second nanostructures arranged in the vertical direction, wherein a number of the second nanostructures is less than a number of the first nanostructures;
a plurality of second epitaxial structures on either side of each of the second nanostructures; and
a second gate structure around the second nanostructures and between the second epitaxial structures;
a first metal contact over one of the first epitaxial structures; and
a second metal contact over one of the second epitaxial structures, wherein a bottom of the second metal contact is deeper than a bottom of the first metal contact.

17. The semiconductor structure of claim 16, wherein a vertical dimension of the second metal contact is greater than a vertical dimension of the first metal contact.

18. The semiconductor structure of claim 16, wherein a vertical dimension of the one of the second epitaxial structures is less than a vertical dimension of the one of the first epitaxial structures.

19. The semiconductor structure of claim 16, further comprising:
a contact etch stop layer over the first and second transistors, wherein the first and second metal contacts pass through the contact etch stop layer, an uppermost one of the first nanostructures and the contact etch stop layer has a first distance therebetween, and an uppermost one of the second nanostructures and the contact etch stop layer has a second distance therebetween, the second distance is greater than the first distance.

20. The semiconductor structure of claim 19, wherein the first distance is in a range from 3-15 nm, and the second distance is in a range from 6-40 nm.
